(19) United States
(12) Patent Application Publication
(10) Pub. No.: US 2025/0123563 A1
(43) Pub. Date: Apr. 17, 2025

(54) POLYMER, RESIST COMPOSITION COMPRISING THE SAME AND METHOD OF FORMING PATTERN USING THE SAME

(71) Applicant: Samsung Electronics Co., Ltd., Suwon-si (KR)

(72) Inventors: Jaejun LEE, Suwon-si (KR); Cheol KANG, Suwon-si (KR); Hana KIM, Suwon-si (KR); Sungan DO, Hwaseong-si (KR); Yonghoon MOON, Hwaseong-si (KR)

(73) Assignee: Samsung Electronics Co., Ltd., Suwon-si (KR)

(21) Appl. No.: 18/601,349

(22) Filed: Mar. 11, 2024

(30) Foreign Application Priority Data
Oct. 13, 2023 (KR) 10-2023-0137032

(51) Int. Cl. G03F 7/039; C08F 218/00; C08F 220/18; C08F 220/30

(52) U.S. Cl. CPC G03F 7/039; C08F 218/24; C08F 220/1807; C08F 220/301

(57) ABSTRACT

Provided are a polymer including a first repeating unit represented by Formula 1 below and a second repeating unit represented by Formula 2 below, a resist composition including the same, and a method of forming a pattern using the same.

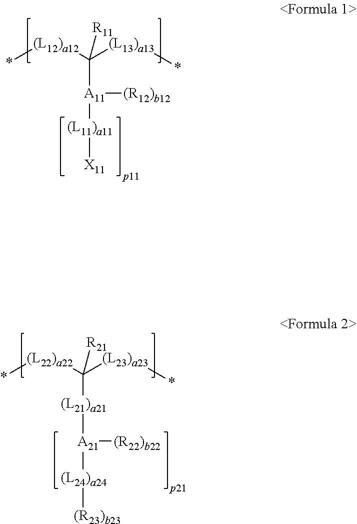

In Formulae 1 and 2, L₁₁ to L₁₃, L₂₁ to L₂₄, a11 to a13, a21 to a24, A₁₁, A₂₁, X₁₁, R₁₁, R₁₂, R₂₁ to R₂₃, b12, b22, b23, p11 and p21 are as described above in the specification.

### CROSS-REFERENCE TO RELATED APPLICATION

This application is based on and claims priority under 35 U.S.C. § 119 to Korean Patent Application No. 10-2023-0137032, filed on Oct. 13, 2023 in the Korean Intellectual Property Office, the disclosure of which is incorporated by reference herein in its entirety.

### BACKGROUND

### 1. Field

The disclosure relates to a polymer, a resist composition including the same, and a method of forming a pattern using the same.

### 2. Description of the Related Art

In semiconductor manufacturing, photoresists, physical properties of which are changed in response to light are used to form fine patterns. Among them, chemically amplified photoresists have been widely used. A chemically amplified photoresist enables patterning because a base resin of the chemically amplified photoresist reacts with an acid produced by reaction between light and a photoacid generator, resulting in a change in solubility of the base resin in a developer.

However, in the case of the chemically amplified photoresist, the produced acid may be diffused to an unexposed region, causing issues such as a decrease in uniformity of a pattern or an increase in surface roughness. In addition, it is difficult to control diffusion of an acid in a semiconductor process that becomes increasingly finer, and thus there is a need to develop a new resist method.

Recently, in order to overcome the limits of chemically amplified photoresists, attempts have been made to develop materials, physical properties of which are changed by exposure to light. However, a dose required for light exposure is still high.

Therefore, there is a need to develop a material, physical properties of which change at a low dose of light via quick reaction.

### SUMMARY

Therefore, provided are a polymer, physical properties, particularly solubility, of which are changed by exposure light even at a low dose of light, a resist composition including the same, and a method of forming a pattern using the same.

Additional aspects will be set forth in part in the description which follows and, in part, will be apparent from the description, or may be learned by practice of the presented embodiments.

According to an embodiment of the disclosure, a polymer may include a first repeating unit represented by Formula 1 below and a second repeating unit represented by Formula 2 below.

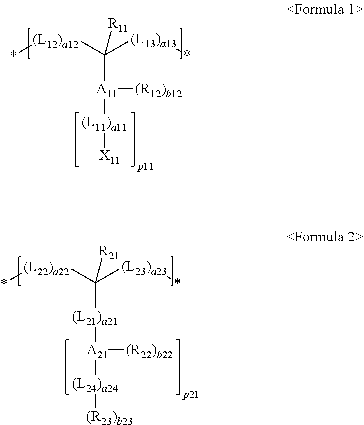

In Formulae 1 and 2,
L₁₁ to L₁₃ and L₂₁ to L₂₄ each independently may be a single bond, O, S, C(═O), C(═O)O, OC(═O), C(═O)NH, NHC(═O), S(═O), S(═O)₂O, OS(═O)₂, or a linear, branched, or cyclic C₁-C₃₀ divalent hydrocarbon group optionally including a heteroatom,
a11 to a13 and a21 to a24 each independently may be an integer from 1 to 4,
A₁₁ and A₂₁ each independently may be a C₆-C₃₀ aryl group or a C₁-C₃₀ heteroaryl group,
X₁₁ may be a photo-degradable group,
R₁₁ may be a halogen atom, or a linear, branched, or cyclic C₁-C₃₀ monovalent hydrocarbon group optionally including a heteroatom,
R₂₁ may be a halogen atom, or a linear, branched, or cyclic C₁-C₃₀ monovalent hydrocarbon group substituted with a halogen atom,
R₁₂ and R₂₂ each independently may be hydrogen, deuterium, a halogen atom, a cyano group, a hydroxyl group, an amino group, a carboxylate group, a thiol group, a carbonyl moiety, an ester moiety, a sulfonate moiety, a carbonate moiety, a lactone moiety, a sultone moiety, a carboxylic anhydride moiety, or a linear, branched, or cyclic C₁-C₃₀ monovalent hydrocarbon group optionally including a heteroatom,
R₂₃ may be hydrogen, deuterium, a halogen atom, a cyano group, a hydroxyl group, an amino group, a carboxylate group, a thiol group, a carbonyl moiety, an ester moiety, a sulfonate moiety, a carbonate moiety, a lactone moiety, a sultone moiety, a carboxylic anhydride moiety, a linear, branched, or cyclic C₁-C₃₀ monovalent hydrocarbon group optionally including a heteroatom, or a photo-degradable group,
b12, b22, and b23 each may be independently an integer from 1 to 10,
p11 may be an integer from 1 to 3,
p21 may be an integer from 0 to 4, and
* may be a binding site with an adjacent atom.

According to an embodiment of the disclosure, a resist composition may include the above-described polymer and an organic solvent.

According to embodiment of the disclosure, a method of forming a pattern may include forming a resist film by applying the above-described resist composition on a substrate, exposing a portion of the resist film to high-energy rays to provide an exposed resist film, and developing the exposed resist film using a developer.

### BRIEF DESCRIPTION OF THE DRAWINGS

The above and other aspects, features, and advantages of certain embodiments will be more apparent from the following description taken in conjunction with the accompanying drawings, in which:

FIG. 1 is a flowchart illustrating a method of forming a pattern according to an embodiment;

FIGS. 2A to 2C are side cross-sectional views showing a method of forming a pattern according to an embodiment;

FIGS. 3A to 3E are side cross-sectional views illustrating a method of forming a patterned structure according to an embodiment; and

FIGS. 4A to 4E are side cross-sectional views illustrating a method of forming a semiconductor device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” if preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As the disclosure below allows for various changes and numerous embodiments, particular embodiments will be illustrated in the drawings and described in detail in the written description. However, this is not intended to limit the disclosure to particular modes of practice, and it is to be appreciated that all modifications, equivalents, and substitutes that do not depart from the spirit and technical scope of the disclosure are encompassed in the disclosure. In the following description of the disclosure, a detailed description of known functions and configurations incorporated herein will be omitted when it may obscure the subject matter of the disclosure.

Although the terms “first”, “second”, “third”, and the like may be used herein to describe various elements, these terms are only used to distinguish one element from another and the order, type, or the like of the elements are not limited thereby.

Throughout the specification, it will be understood that when one element such as layer, film, region, or plate, is referred to as being “on” another element, it may be directly on the other element or intervening elements may also be present therebetween.

An expression used in the singular encompasses the expression of the plural, unless it has a clearly different meaning in the context. In the present specification, it is to be understood that the terms such as “including” or “having,” etc., are intended to indicate the existence of the features, numbers, processes, operations, elements, parts, components, materials, or combinations thereof disclosed in the specification, and are not intended to preclude the possibility that one or more other features, numbers, processes, operations, elements, parts, components, materials, or combinations thereof may exist or may be added, unless otherwise stated.

Whenever a range of values is recited, the range includes all values corresponding to the range as clearly recited and also includes boundaries of the range. Therefore, a range “X to Y” includes all numbers between X and Y and also includes X and Y.

As used herein, the term “Cₓ-C_{y}” means that the number of carbon atoms constituting a substituent is from x to y. For example, the term “C₁-C₆” means that the number of carbon atoms constituting a substituent is from 1 to 6, and the term “C₆-C₂₀” means that the number of carbon atoms constituting a substituent is from 6 to 20.

As used herein, the term “monovalent hydrocarbon group” refers to a monovalent moiety derived from an organic compound including carbon and hydrogen or derivatives thereof, and examples thereof may include a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cycloaliphatic hydrocarbon group (a cycloalkyl group, e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); a monovalent unsaturated aliphatic hydrocarbon group (an alkenyl group or an alkynyl group, e.g., an allyl group); a monovalent unsaturated cycloaliphatic hydrocarbon group (cycloalkenyl group, e.g., a 3-cyclohexenyl group); an aryl group (e.g., a phenyl group, a 1-naphthyl group, and a 2-naphthyl group); an arylalkyl group (e.g., a benzyl group and a diphenylmethyl group); a heteroatom-containing monovalent hydrocarbon group (e.g., a tetrahydrofuranyl group, a methoxymethyl group, an ethoxymethyl group, a methylthiomethyl group, an aceteamidemethyl group, a trifluoroethyl group, a 2-(methoxyethoxy)methyl group, an acetoxymethyl group, a 2-carboxyl-1-cyclohexyl group, a 2-oxopropyl group, a 4-oxo-1-adamantyl group, and a 3-oxocyclohexyl group), or any combination thereof. Also, in these groups, some hydrogen atoms may be substituted with a moiety including a heteroatom, such as oxygen, sulfur, or nitrogen, or a halogen atom, or some carbon atoms may be substituted with a moiety including a heteroatom, such as oxygen, sulfur, or nitrogen, and thus these groups may include a hydroxyl group, a cyano group, a carboxyl group, an ether bond, a carbonyl moiety, an ester moiety, a sulfonate moiety, a carbonate moiety, a lactone moiety, a sultone moiety, a carboxylic anhydride moiety, or a haloalkyl moiety.

As used herein, the term “divalent hydrocarbon group” refers to a divalent moiety in which at least one hydrogen atom of the monovalent hydrocarbon group is substituted with a binding site with an adjacent atom. The divalent hydrocarbon group may include, for example, a linear or branched alkylene group, a cycloalkylene group, an alkenylene group, an alkynylene group, a cycloalkylene group, an arylene group, and those in which some carbon atoms are replaced with a heteroatom.

As used herein, the term “alkyl group” refers to a linear or branched monovalent saturated aliphatic hydrocarbon group, and examples thereof include a methyl group, an ethyl group, a propyl group, an isobutyl group, a sec-butyl group, a tert-butyl group, a pentyl group, an iso-amyl group, and a hexyl group. As used herein, the term “alkylene group” refers to a linear or branched divalent saturated aliphatic hydrocarbon group, and examples thereof include a methylene group, an ethylene group, a propylene group, a butylene group, and an isobutylene group.

As used herein, the term “halogenated alkyl group” refers to a group in which at least one hydrogen atom of an alkyl group is substituted with a halogen atom, and examples thereof include CF₃.

As used herein, the term “alkoxy group” refers to a monovalent group represented by formula —OA₁₀₁, where A₁₀₁ is an alkyl group. Examples thereof include a methoxy group, an ethoxy group, and an isopropyloxy group.

As used herein, the term “alkylthio group” refers to a monovalent group represented by formula —SA₁₀₁, where A₁₀₁ is an alkyl group.

As used herein, the term “halogenated alkoxy group” refers to an alkoxy group, at least one hydrogen atom of which is substituted with a halogen atom, and examples thereof include —OCF₃.

As used herein, the term “halogenated alkylthio group” refers to an alkylthio group, at least one hydrogen atom of which is substituted with a halogen atom, and examples thereof include —SCF₃.

As used herein, the term “cycloalkyl group” refers to a monovalent saturated hydrocarbon cyclic group, and examples thereof include a monocyclic group such as a cyclopropyl group, a cyclobutyl group, a cyclopentyl group, a cyclohexyl group, and a cycloheptyl group and a condensed polycyclic group such as a norbonyl group and an adamantly group. As used herein, the term “cycloalkylene group” refers a divalent saturated hydrocarbon cyclic group, and examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, and a dicyclohexylmethylene group.

As used herein, the term “cycloalkoxy group” refers to a monovalent group represented by formula —OA₁₀₂, where A₁₀₂ is a cycloalkyl group. Examples thereof include a cyclopropoxy group and a cyclobutoxy group.

As used herein, the term “cycloalkylthio group” refers to a monovalent group represented by formula —SA₁₀₂, where A₁₀₂ is a cycloalkyl group.

As used herein, the term “heterocycloalkyl group” refers to a cycloalkyl group in which some carbon atoms are substituted with a moiety including a heteroatom, such as oxygen, sulfur, or nitrogen, and the heterocycloalkyl group may specifically include an ether bond, an ester bond, a sulfonate bond, a carbonate, a lactone ring, a sultone ring, or a carboxylic anhydride moiety. As used herein, the term “heterocycloalkylene group” refers to a cycloalkylene group in which some carbon atoms are substituted with a moiety including a heteroatom such as oxygen, sulfur, or nitrogen.

As used herein, the term “heterocycloalkoxy group” refers to a monovalent group represented by formula —OA₁₀₃, where A₁₀₃ is a heterocycloalkyl group.

As used herein, the term “alkenyl group” refers to a linear or branched monovalent unsaturated aliphatic hydrocarbon group including at least one carbon-carbon double bond. As used herein, the term “alkenylene group” refers to a linear or branched divalent saturated aliphatic hydrocarbon group including at least one carbon-carbon double bond.

As used herein, the term “alkenyloxy group” refers to a monovalent group represented by formula —OA₁₀₄, where A₁₀₄ is an alkenyl group.

As used herein, the term “cycloalkenyl group” refers to a monovalent unsaturated hydrocarbon cyclic group including at least one carbon-carbon double bond. As used herein, the term “cycloalkenylene group” refers to a divalent unsaturated hydrocarbon cyclic group including at least one carbon-carbon double bond.

As used herein, the term “cycloalkenyloxy group” refers to a monovalent group represented by formula —OA₁₀₅, where A₁₀₅ is an cycloalkenyl group.

As used herein, the term “heterocycloalkenyl group” refers to a cycloalkenylene group in which some carbon atoms are substituted with a moiety including a heteroatom, such as oxygen, sulfur, or nitrogen. As used herein, the term “heterocycloalkenylene group” refers to a cycloalkenylene group in which some carbon atoms are substituted with a moiety including a heteroatom, such as oxygen, sulfur, or nitrogen.

As used herein, the term “heterocycloalkenyloxy group” refers to a monovalent group represented by formula —OA₁₀₆, where A₁₀₆ is a heterocycloalkenyl group.

As used herein, the term “alkynyl group” refers to a linear or branched monovalent unsaturated aliphatic hydrocarbon group including at least one carbon-carbon triple bond.

As used herein, the term “alkynyloxy group” refers to a monovalent group represented by formula —OA₁₀₇, where A₁₀₇ is an alkynyl group.

As used herein, the term “aryl group” refers to a monovalent group including a carbocyclic aromatic system, and examples thereof include a phenyl group, a naphthyl group, an anthracenyl group, a phenanthrenyl group, a pyrenyl group, and a chrysenyl group.

As used herein, the term “aryloxy group” refers to a monovalent group represented by formula —OA₁₀₈, where A₁₀₈ is an aryl group.

As used herein, the term “heteroaryl group” refers to a monovalent group including a heterocyclic aromatic system, and examples thereof include a pyridinyl group, a pyrimidinyl group, and a pyrazinyl group. As used herein, the term “heteroarylene group” refers to a divalent group including a heterocyclic aromatic system.

As used herein, the term “heteroaryloxy group” refers to a monovalent group represented by formula —OA₁₀₉, where A₁₀₉ is a heteroaryl group.

As used herein, the term “substituent” includes deuterium, a halogen atom, a hydroxyl group, a cyano group, a nitro group, a carboxylate group, an amino group, an ether moiety, a carbonyl moiety, an ester moiety, a sulfonate moiety, a carbonate moiety, a carbamate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group; and
a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group; and any combination thereof, which are unsubstituted or substituted with deuterium, a halogen atom, a hydroxyl group, a cyano group, a nitro group, a carboxylate group, an amino group, an ether moiety, a carbonyl moiety, an ester moiety, a sulfonate moiety, a carbonate moiety, a carbamate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, and any combination thereof.

Hereinafter, embodiments will be described in detail with reference to the accompanying drawings. In the drawings, like reference numerals denote like elements or components having substantially same functions, and duplicate descriptions will be omitted. In the drawings, thicknesses of various layers and regions are enlarged for clarity. In the drawings, for convenience of explanation, thicknesses of some layers and regions are exaggerated for clarity. Meanwhile, it should be understood that embodiments described hereinafter are merely for illustrative purposes, various changes in form from the embodiments may be made.

### [Polymer]

The polymer according to an embodiment includes a first repeating unit represented by Formula 1 below and a second repeating unit represented by Formula 2 below.

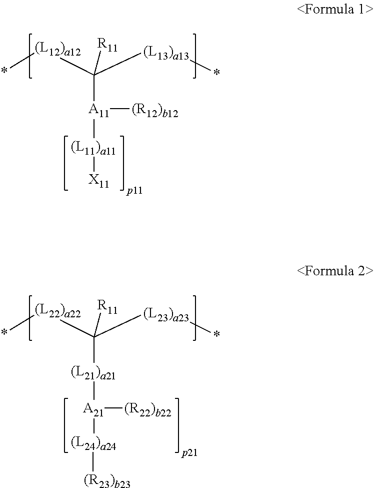

In Formulae 1 and 2,
L₁₁ to L₁₃ and L₂₁ to L₂₄ are each independently a single bond; O; S; C(═O); C(═O)O; OC(═O); C(═O)NH; NHC(═O); S(═O); S(═O)₂O; OS(═O)₂; or a linear, branched, or cyclic C₁-C₃₀ divalent hydrocarbon group optionally including a heteroatom,
a11 to a13 and a21 to a24 are each independently an integer from 1 to 4,
A₁₁ and A₂₁ are each independently a C₆-C₃₀ aryl group or a C₁-C₃₀ heteroaryl group,
X₁₁ is a photo-degradable group,
R₁₁ is a halogen atom, or a linear, branched, or cyclic C₁-C₃₀ monovalent hydrocarbon group optionally including a heteroatom,
R₂₁ is a halogen atom, or a linear, branched, or cyclic C₁-C₃₀ monovalent hydrocarbon group substituted with a halogen atom,
R₁₂ and R₂₂ are each independently: hydrogen; deuterium; a halogen atom; a cyano group; a hydroxyl group; an amino group; a carboxylate group; a thiol group; a carbonyl moiety; an ester moiety; a sulfonate moiety; a carbonate moiety; a lactone moiety; a sultone moiety; a carboxylic anhydride moiety; or a linear, branched, or cyclic C₁-C₃₀ monovalent hydrocarbon group optionally including a heteroatom,
R₂₃ is hydrogen; deuterium; a halogen atom; a cyano group; a hydroxyl group; an amino group; a carboxylate group; a thiol group; a carbonyl moiety; an ester moiety; a sulfonate moiety; a carbonate moiety; a lactone moiety; a sultone moiety; a carboxylic anhydride moiety; a linear, branched, or cyclic C₁-C₃₀ monovalent hydrocarbon group optionally including a heteroatom; or a photo-degradable group,
b12, b22, and b23 are each independently an integer from 1 to 10,
p11 is an integer from 1 to 3,
p21 is an integer from 0 to 4, and
is a binding site with an adjacent atom.

For example, in Formulae 1 and 2, L₁₁ to L₁₃ and L₂₁ to L₂₄ may be each independently: a single bond; O; S; C(═O); C(═O)O; OC(═O); C(═O)NH; NHC(═O); S(═O); S(═O)₂O; OS(═O)₂; a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ arylene group.

As another example, in Formulae 1 and 2, L₁₁ to L₁₃ and L₂₁ to L₂₄ may be each independently selected from: a single bond; O; C(═O); C(═O)O; OC(═O); C(═O)NH; NHC(═O); S(═O); S(═O)₂O; OS(═O)₂; and a C₁-C₂₀ alkylene group, a C₃-C₂₀ cycloalkylene group, a C₃-C₂₀ heterocycloalkylene group, a C₂-C₂₀ alkenylene group, a C₃-C₂₀ cycloalkenylene group, a C₃-C₂₀ heterocycloalkenylene group, a C₆-C₂₀ arylene group, and a C₁-C₂₀ heteroarylene group, which are unsubstituted or substituted with deuterium, a halogen atom, a cyano group, a hydroxyl group, an amino group, a carboxylate group, a thiol group, a carbonyl moiety, an ester moiety, a sulfonate moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

As another example, in Formulae 1 and 2, L₁₁ to L₁₃ and L₂₁ to L₂₄ may be each independently selected from: a single bond; O; C(═O); C(═O)O; OC(═O); C(═O)NH; NHC(═O); S(═O); S(═O)₂O; OS(═O)₂; and a C₁-C₂₀ alkylene group, a C₃-C₂₀ cycloalkylene group, a C₃-C₂₀ heterocycloalkylene group, a phenylene group, and a naphthylene group, which are unsubstituted or substituted with deuterium, a halogen atom, a C₁-C₂₀ alkyl group, a C₁-C₂₀ halogenated alkyl group, a C₁-C₂₀ alkoxy group, a phenyl group, a naphthyl group, or any combination thereof.

In Formulae 1 and 2, a11 to a13 and a21 to a24 each independently refer to the number of repeating times of L₁₁ to L₁₃ and L₂₁ to L₂₄.

For example, in Formulae 1 and 2, a11 to a13 and a21 to a24 each independently may be an integer from 1 to 3.

As another example, in Formulae 1 and 2, a11 to a13 and a21 to a24 may be each independently 1.

For example, in Formulae 1 and 2, A₁₁ and A₂₁ may be each independently selected from a phenyl group, a biphenyl group, a terphenyl group, a naphthyl group, a phenanthrenyl group, an anthracenyl group, a triphenylenyl group, a pyrenyl group, a chrysenyl group, a pyrrolyl group, a thiophenyl group, a furanyl group, an imidazolyl group, a pyrazolyl group, a thiazolyl group, an oxazolyl group, a pyridinyl group, a pyrazinyl group, a pyrimidinyl group, a pyridazinyl group, an indolyl group, a quinolinyl group, an isoquinolinyl group, a benzoquinolinyl group, a quinoxalinyl group, a quinazolyl group, and a cinnolinyl group.

Specifically, in Formulae 1 and 2, A₁₁ and A₂₁ may be each independently selected from a phenyl group, a biphenyl group, a terphenyl group, and a naphthyl group.

For example, in Formula 1, X₁₁ may include a tertiary acyclic alkyl carbon-containing group, a tertiary alicyclic carbon-containing group, acetal, or an O—N bond-containing group.

Specifically, in Formula 1, X₁₁ may be a tertiary acyclic alkyl carbon-containing ester group, a tertiary alicyclic carbon-containing ester group, a tertiary acyclic alkyl carbon-containing carbonate group, a tertiary alicyclic carbon-containing carbonate group, a tertiary acyclic alkyl carbon-containing carbamate group, a tertiary alicyclic carbon-containing carbamate group, acetal, a sulfonate group, or an O—N bond-containing group.

In an embodiment, in Formula 1, X₁₁ may be represented by one of Formulae 6-1 to 6-14 below.

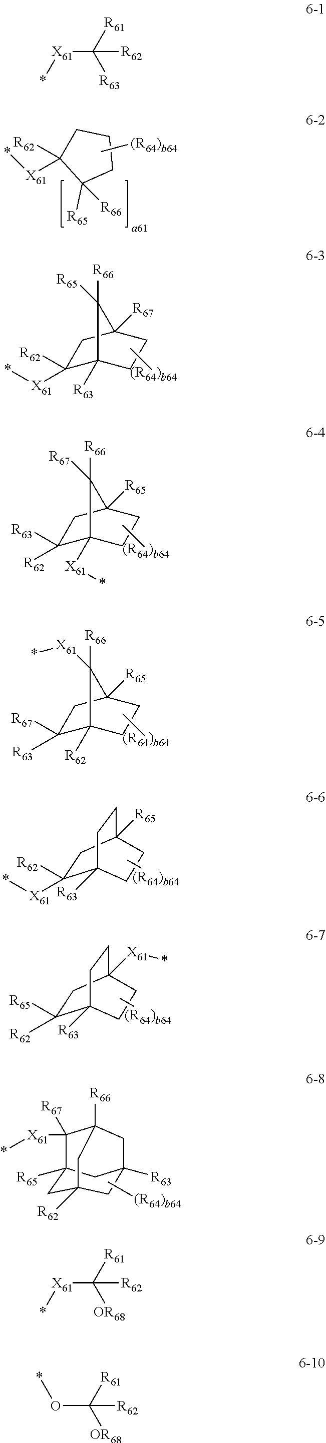

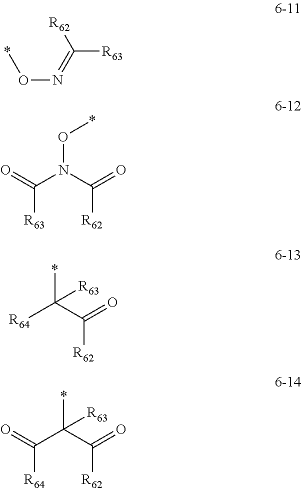

In Formulae 6-1 to 6-14,
X₆₁ is an ester moiety, a carbonate moiety, a carbamate moiety, or a sulfonate moiety;
a61 is an integer from 0 to 6;
R₆₁ and R₆₈ are each independently a linear, branched, or cyclic C₁-C₂₀ monovalent hydrocarbon group optionally including a heteroatom;
R₆₂ to R₆₇ are each independently: hydrogen; deuterium; a halogen atom; a cyano group; a hydroxyl group; an amino group; a carboxylate group; a thiol group; a carbonyl moiety; an ester moiety; a sulfonate moiety; a carbonate moiety; a carbamate moiety; a lactone moiety; a sultone moiety; a carboxylic anhydride moiety; or a linear, branched, or cyclic C₁-C₃₀ monovalent hydrocarbon group optionally including a heteroatom,
among R₆₁ to R₆₈, two adjacent ones optionally bind to each other to form a ring,
b64 is an integer from 1 to 10, and
* is a binding site with an adjacent atom.

For example, in Formula 1, R₁₁ may be a halogen atom, a substituted or unsubstituted C₁-C₂₀ alkyl group, or a substituted or unsubstituted C₁-C₂₀ haloalkyl group.

Specifically, in Formula 1, R₁₁ may be F, CH₃, CH₂CH₃, CH₂F, CHF₂, CF₃, CHFCH₃, CHFCH₂F, CHFCHF₂, CHFCF₃, CF₂CH₃, CF₂CH₂F, CF₂CHF₂, or CF₂CF₃.

For example, in Formula 2, R₂₁ may be a halogen atom, or a substituted or unsubstituted C₁-C₂₀ haloalkyl group.

Specifically, in Formula 2, R₂₁ may be F, CH₂F, CHF₂, CF₃, CHFCH₃, CHFCH₂F, CHFCHF₂, CHFCF₃, CF₂CH₃, CF₂CH₂F, CF₂CHF₂, CF₂CF₃, Cl, CH₂Cl, CHCl₂, CCl₃, CHClCH₃, CHClCH₂Cl, CHClCHCl₂, CHClCCl₃, CCl₂CH₃, CCl₂CH₂Cl, CCl₂CHCl₂, or CCl₂CCl₃.

For example, in Formulae 1 and 2, R₁₂ and R₂₂ may be each independently selected from: hydrogen; deuterium; a halogen atom; a cyano group; a hydroxyl group; an amino group; a carboxylate group; a thiol group; and a C₁-C₂₀ alkyl group, a C₃-C₂₀ cycloalkyl group, and a C₆-C₂₀ aryl group, which are unsubstituted or substituted with deuterium, a halogen atom, a cyano group, a hydroxyl group, an amino group, a carboxylate group, a thiol group, a carbonyl moiety, an ester moiety, a sulfonate moiety, a carbonate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

Specifically, in Formulae 1 and 2, R₁₂ and R₂₂ may be each independently: hydrogen; deuterium; a halogen atom; a cyano group; a hydroxyl group; an amino group; a carboxylate group; a thiol group; a C₁-C₂₀ alkyl group; a C₁-C₂₀ halogenated alkyl group; a C₃-C₂₀ cycloalkyl group; or a C₆-C₂₀ aryl group.

For example, in Formula 2, R₂₃ may be selected from: a photo-degradable group; hydrogen; deuterium; a halogen atom; a cyano group; a hydroxyl group; an amino group; a carboxylate group; a thiol group; and a C₁-C₂₀ alkyl group, a C₃-C₂₀ cycloalkyl group, and a C₆-C₂₀ aryl group, which are unsubstituted or substituted with deuterium, a halogen atom, a cyano group, a hydroxyl group, an amino group, a carboxylate group, a thiol group, a carbonyl moiety, an ester moiety, a sulfonate moiety, a carbonate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

Specifically, in Formula 2, R₂₃ may be: a photo-degradable group; hydrogen; deuterium; a halogen atom; a cyano group; a hydroxyl group; an amino group; a carboxylate group; a thiol group; a C₁-C₂₀ alkyl group; a C₁-C₂₀ halogenated alkyl group; a C₃-C₂₀ cycloalkyl group; or a C₆-C₂₀ aryl group.

For example, in Formula 1, p11 may be 1.

For example, in Formula 2, p21 may be 0 or 1.

In an embodiment, the first repeating unit may be represented by Formula 1-1 below.

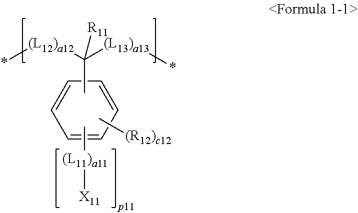

In Formula 1-1,
L₁₁ to L₁₃, a11 to a13, X₁₁, R₁₁, R₁₂ and p11 are as described above,
c12 is an integer from 1 to 4, and
* is a binding site with an adjacent atom.

Specifically, the first repeating unit may be selected from compounds of Group I below.

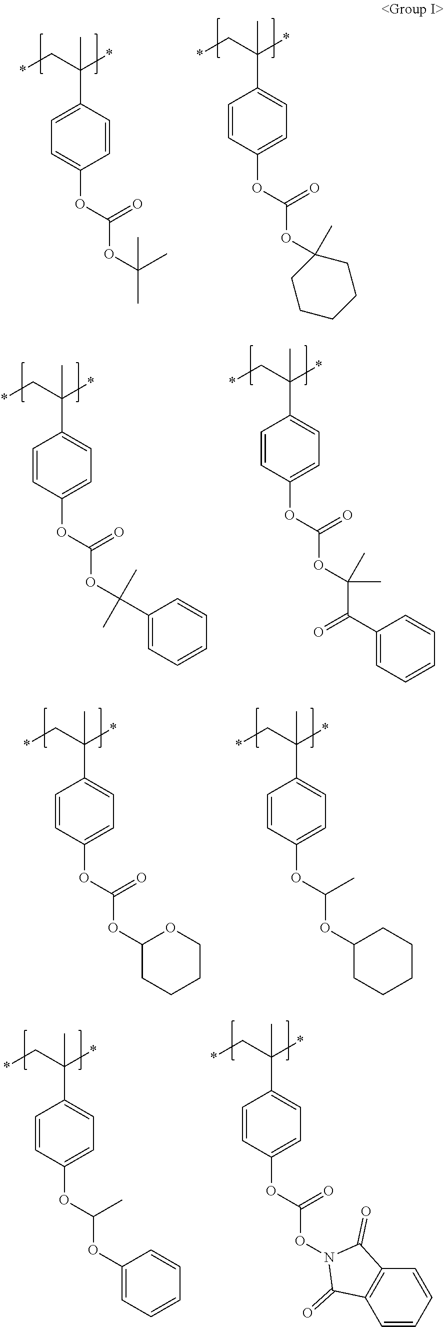

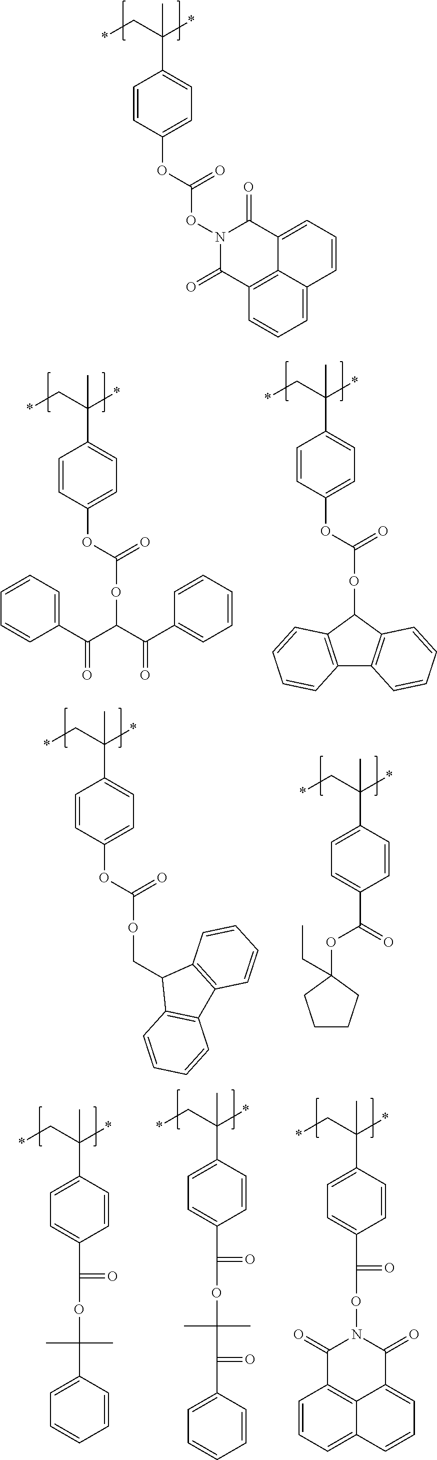

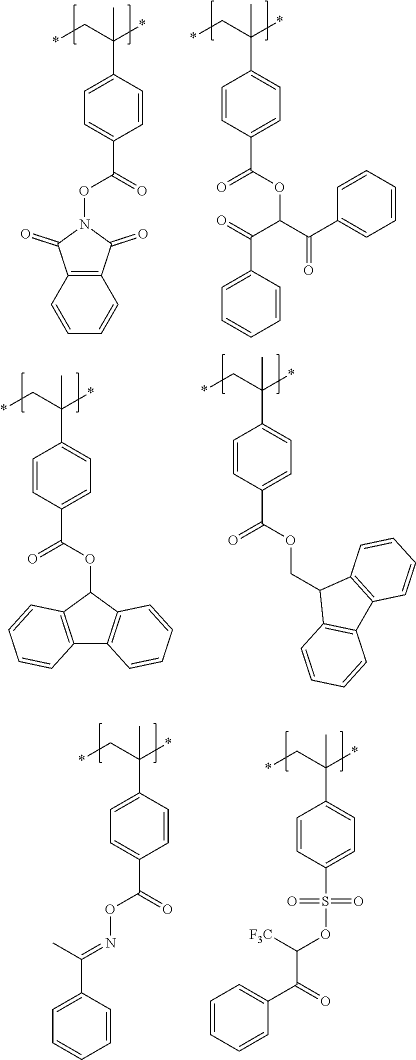

In an embodiment, the second repeating unit may be represented by one of Formulae 2-1 and 2-2 below.

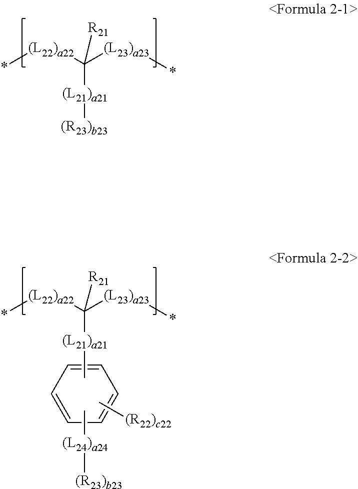

In Formulae 2-1 and 2-2,
L₂₁ to L₂₄, a21 to a24, R₂₁ to R₂₃ and b23 are as defined in Formula 2,
c22 is an integer from 1 to 4, and
* is a binding site with an adjacent atom.

In an embodiment, the second repeating unit may be selected from compounds of Group II below.

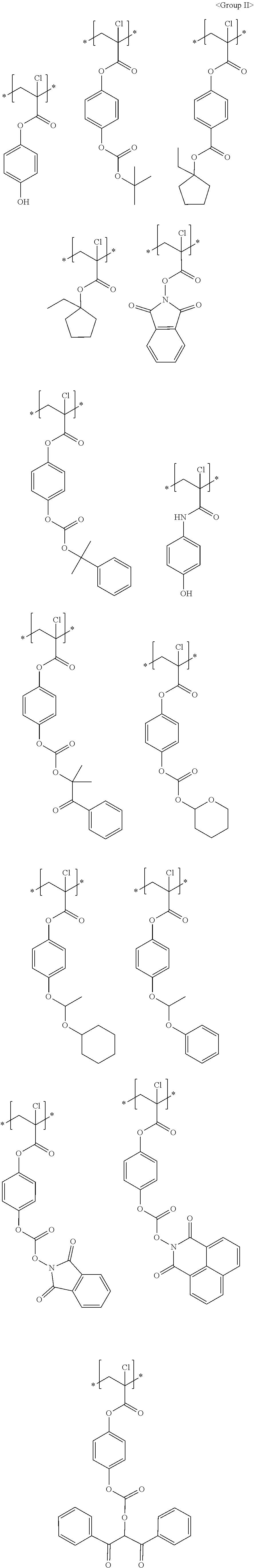

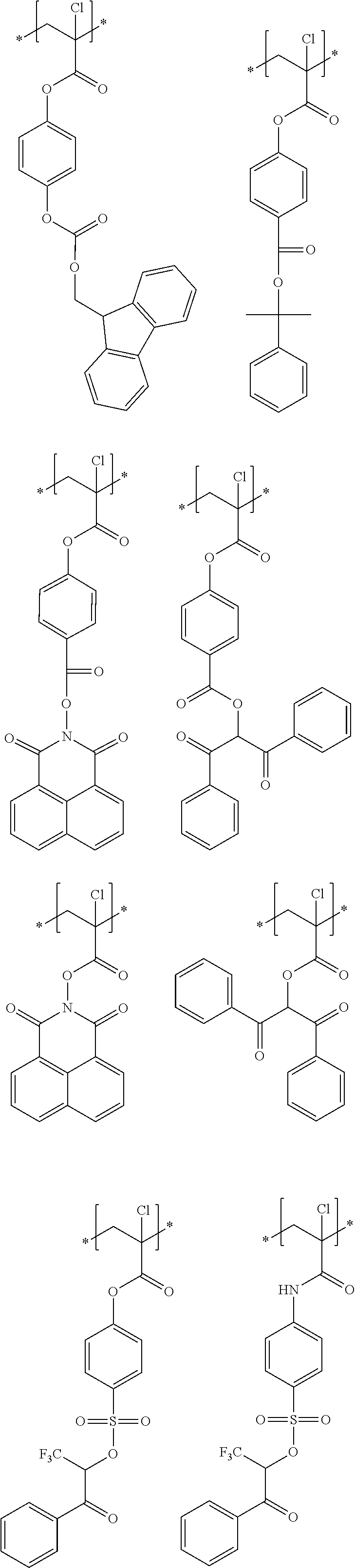

In an embodiment, the polymer may include (or consist of) the first repeating unit and the second repeating unit. Specifically, the polymer may include about 1 mol % to about 99 mol % of the first repeating unit and about 1 mol % to about 99 mol % of the second repeating unit. More specifically, the polymer may include about 20 mol % to about 90 mol % of the first repeating unit and about 10 mol % to about 80 mol % of the second repeating unit. Particularly, the first repeating unit and the second repeating unit may be included in the polymer in a molar ratio of about 5:1 to about 1:5.

The polymer may further include a third repeating unit represented by Formula 3 below.

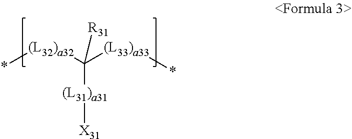

In Formula 3,
L₃₁ to L₃₃ are each independently: a single bond; O; S; C(═O); C(═O)O; OC(═O); C(═O)NH; NHC(═O); S(═O); S(═O)₂O; OS(═O)₂; or a linear, branched, or cyclic C₁-C₃₀ divalent hydrocarbon group optionally including a heteroatom,
a31 to a33 are each independently an integer from 1 to 4,
R₃₁ is: hydrogen; deuterium; a halogen atom; a cyano group; a hydroxyl group; an amino group; a carboxylate group; a thiol group; a carbonyl moiety; an ester moiety; a sulfonate moiety; a carbonate moiety; a lactone moiety; a sultone moiety; a carboxylic anhydride moiety; or a linear, branched, or cyclic C₁-C₃₀ monovalent hydrocarbon group optionally including a heteroatom,
X₃₁ is a photo-degradable group or a non-acid labile group, and
* is a binding site with an adjacent atom.

In Formula 3, L₃₁ to L₃₃ are as described above in L₁₁ of Formula 1.

In Formula 3, a31 to a33 are as described above in all of Formula 1.

In Formula 3, R₃₁ is as described above in R₁₂ of Formula 1.

In Formula 3, the photo-degradable group is as described above in X₁₁ of Formula 1.

In Formula 3, the non-acid labile group may be: hydrogen; a halogen atom; a cyano group; a hydroxyl group; a carboxylate group; a thiol group; an amino group; or a linear, branched, or cyclic C₁-C₃₀ monovalent hydrocarbon group optionally including a halogen atom, a cyano group, a hydroxyl group, a thiol group, a carboxylate group, O, C═O, C(═O)O, OC(═O), S(═O)₂O, OS(═O)₂, a lactone moiety, a sultone moiety, and a carboxylic anhydride moiety.

In an embodiment, the non-acid labile group of Formula 3 may be one selected of hydrogen, a hydroxyl group, and compounds represented by Formulae 5-1 to 5-12 below.

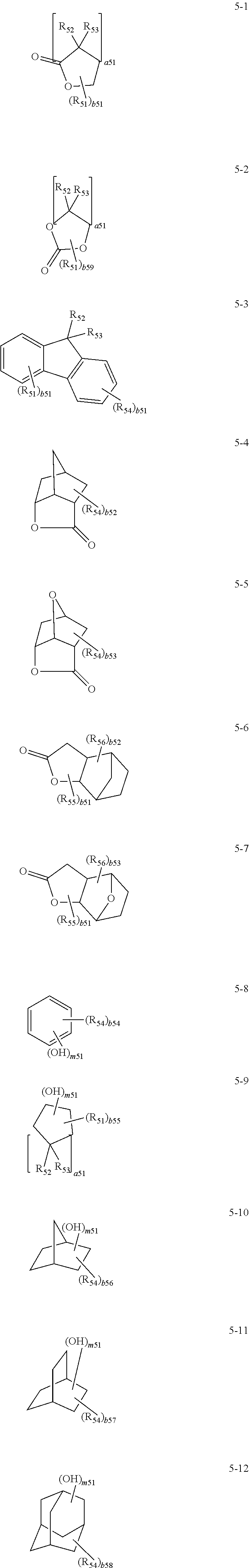

In Formulae 5-1 to 5-12,
a51 may be 1 or 2;
R₅₁ to R₅₆ may be each independently: a binding site with an adjacent atom; hydrogen; a hydroxyl group; a carboxylate group; a carbonyl moiety; an ester moiety; a carbonate moiety; a carbamate moiety; a lactone moiety; a carboxylic anhydride moiety; or a linear, branched, or cyclic C₁-C₂₀ monovalent hydrocarbon group,
one of R₅₁ to R₅₃, one of R₅₄, and one of R₅₅ and R₅₆ may be a binding site with an adjacent atom,
b51 may be an integer from 1 to 4
b52 may be an integer from 1 to 10,
b53 may be an integer from 1 to 8,
b54 may be an integer from 1 to 5,
b55 may be an integer from 1 to 7,
b56 may be an integer from 1 to 11,
b57 may be an integer from 1 to 13,
b58 may be an integer from 1 to 15,
b59 may be an integer from 1 to 2, and
m51 may be an integer from 1 to 4.

Particularly, the non-acid labile group of Formula 3 may be selected from a hydroxyl group, and compounds represented by Formulae 5-1, 5-6, and 5-10.

In an embodiment, the third repeating unit may be selected from compounds of Group III below.

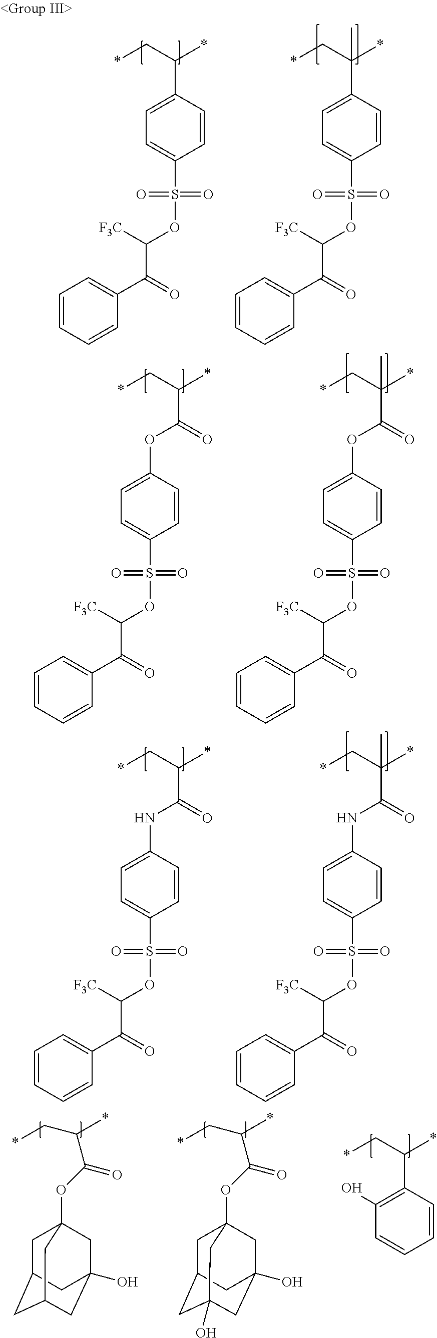

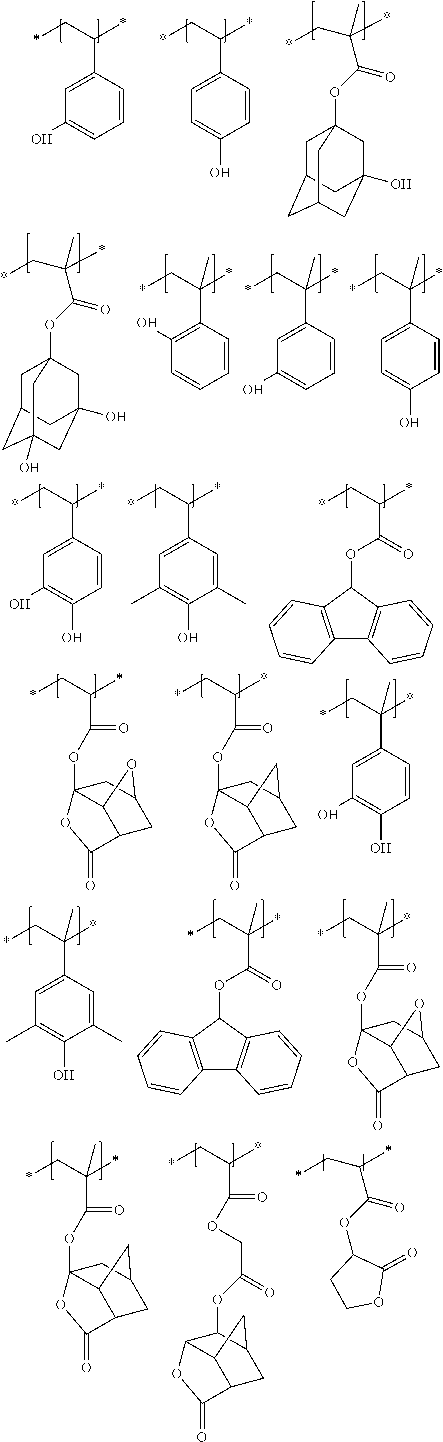

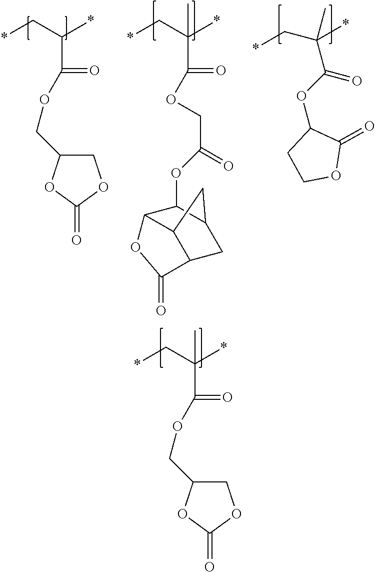

In an embodiment, the polymer may include (or consist of) the first repeating unit, the second repeating unit, and the third repeating unit. The polymer may include about 1 mol % to about 98 mol % of the first repeating unit, about 1 mol % to about 98 mol % of the second repeating unit, and about 1 mol % to about 98 mol % of the third repeating unit. Particularly, the first repeating unit and the third repeating unit may be included in the polymer in a molar ratio of about 10:1 to about 1:10.

The polymer may have a weight average molecular weight Mw of about 1,000 to about 500,000, specifically, about 3,000 to about 200,000, more specifically, about 5,000 to about 50,000, measured by gel permeation chromatography using a tetrahydrofuran solvent and polystyrene as a standard material.

The polymer may have a polydispersity index (PDI: Mw/Mn) of about 1.0 to about 3.0. In the case where the above-described range is satisfied, dispersity and/or compatibility of the polymer may be easily controlled, a possibility of foreign substances remaining on the pattern may be reduced, or deterioration of a pattern profile may be minimized. Accordingly, the resist composition may become more suitable for forming fine patterns.

Because physical properties of the polymer itself may change by high-energy rays, the polymer may be used in non-chemically amplified resist compositions. Specifically, while a main chain of the polymer is decomposed, a molecular weight of the polymer decreases resulting in an increase in solubility in a developer.

In addition, because Ru of the polymer is not hydrogen, stability of a radical generated as a result of decomposition of the main chain may be improved, and thus decomposition rate and/or speed of the main chain may be increased compared to a polymer including hydrogen as Rn.

This will be described in more detail. In general, a decomposition mechanism of a copolymer of a-alkyl styrene having a substituent at the a position and α-haloacrylate by high energy rays may be expressed as Scheme 1. In the polymer decomposition reaction, after dissociation of a halogen ion occurs, β-scission of a radical obtained thereby occurs. In this case, a decomposition rate may be increased as R₁ on the carbon in the R position more stabilizes the radical. Accordingly, the decomposition rate of the polymer including an alkyl group as a substituent may be greater than that of a polymer including hydrogen as R₁.

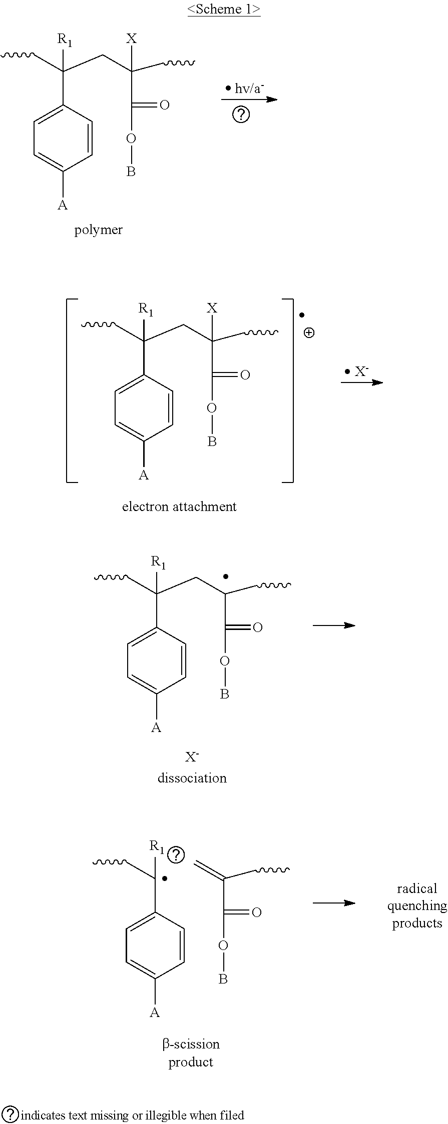

Additionally, the Gaussian simulation was conducted on a polymer represented by Formula A according to the density functional theory (DFT) to identify a reaction velocity of the main chain of the polymer depending on types of the substituent.

As shown in Table 1 below, it was confirmed that the polymer including a methyl group or chlorine as R₁ and a methyl group or chlorine as R₂ suggested by the disclosure has a lower bond dissociation energy (BDE) than a polymer including hydrogen or fluorine as R₁ and fluorine as R₂. That is, the polymer including a methyl group or chlorine as R₁ and a methyl group or chlorine as R₂ may be easily decomposed by high energy rays.

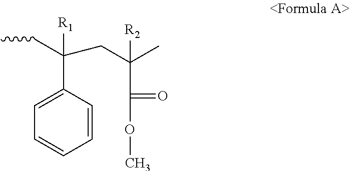

TABLE 1

| BDE | | R₂ | | | |
|---|---|---|---|---|---|
| (kJ/mol) | | H | F | CH₃ | Cl |
| R₁ | H | 317 | 302 | 284 | 282 |
| | F | 318 | 299 | 279 | 280 |
| | CH₃ | 309 | 291 | 270 | 269 |
| | Cl | 293 | 271 | 250 | 253 |

In addition, because the polymer includes a photo-degradable group at a side chain, solubility of the polymer in a developer, particularly, in a basic developer not including an organic solvent may be increased as a result of decomposition of side chains by high energy rays. Therefore, environment pollution may be reduced compared to other positive resist compositions using an organic solvent as a developer.

In addition, because the first repeating unit of the polymer includes both the photo-degradable group and R₁₁ rather than hydrogen, not only decomposition reaction of the main chain of the polymer occurs quickly by high energy rays, but also decomposition reaction for detachment of side chains occurs simultaneously. Finally, as the molecular weight of the polymer, which has a high molecular weight, is reduced and an amount (or concentration) of polar functional groups soluble in a basic developer is increased relative to the initial stage of exposure, solubility in the developer is further increased, and thus a fine pattern with an increased resolution may be efficiently formed even with a lower exposure dose.

Because the second repeating unit of the polymer includes R₂₁, not only the decomposition rate of the polymer may be increased even at a low dose of high energy rays, but also a fine pattern with an increased resolution may be efficiently formed by reducing the molecular weight of the polymer at a low dose.

Because the polymer has relatively high resistance to oxygen and/or moisture and have physical properties changed only by high-energy rays, a resist composition having improved physical properties such as storage stability may be provided.

Unlike chemically amplified photoresists, which may cause problems such as low uniformity of a pattern or high surface roughness by an acid produced and diffused to an unexposed region, the solubility of the polymer is not changed by the acid, and thus the problems of low uniformity of the pattern and/or generation of defects caused by diffusion of the acid may be reduced.

The polymer may be manufactured by any appropriate methods, for example, by a method of dissolving a monomer(s) containing unsaturated bonds in an organic solvent and performing thermal polymerization in the presence of a radical initiator.

The structure (composition) of the polymer may be identified by FT-IR analysis, NMR analysis, X-ray fluorescence (XRF) analysis, mass spectrometry, UV analysis, single crystal X-ray diffraction, powder X-ray diffraction (PXRD), liquid chromatography (LC), size-exclusion chromatography (SEC), thermal analysis, or the like. Detailed descriptions for identification methods therefor are as shown in the examples below.

### [Resist Composition]

According to another aspect, a resist composition includes the above-described polymer and an organic solvent. The resist composition may have enhanced characteristics such as improved developability and/or increased resolution.

Exposure to high-energy rays changes solubility of the resist composition in a developer. The resist composition may be a positive resist composition to form a positive resist pattern by dissolving and removing an exposed portion of a resist film.

Also, the resist composition according to an embodiment may be one for an alkaline developing process using an alkaline developer for development while forming a resist pattern or one for a solvent developing process using an organic solvent-containing developer (hereinafter, referred to as organic developer) for development. Particularly, the resist composition according to an embodiment may be one for an alkaline developing process.

The resist composition may include (or may not substantially include) a compound having a molecular weight of 1,000 or more in addition to the polymer because physical properties of the polymer are changed by light exposure.

The polymer may be used in an amount of about 0.1 parts by weight to about 80 parts by weight based on 100 parts by weight of the resist composition. Specifically, the polymer may be used in an amount of about 0.5 parts by weight to about 5 parts by weight based on 100 parts by weight of the resist composition. In the case where the above-described range is satisfied, loss of performance, e.g., a decrease in sensitivity and/or formation of particles of foreign matter caused by insufficient solubility may be reduced.

Because the polymer is as described above, hereinafter, the organic solvent and optional components included, if required, will be described. In addition, the polymer used may be used alone in the resist composition or at least two thereof may be used in combination.

### <Organic Solvent>

The organic solvent included in the resist composition is not particularly limited, as long as the polymer and any component contained therein, if required, may be dissolved or dispersed therein. The organic solvent may be used alone or any combination of two or more different organic solvents may also be used. Also, a mixed solvent of water and an organic solvent may be used.

Examples of the organic solvent may include alcohol-based solvents, ether-based solvents, ketone-based solvents, amide-based solvents, ester-based solvents, sulfoxide-based solvents, and hydrocarbon-based solvents.

More specifically, examples of the alcohol-based solvents may include: a monoalcohol-based solvent such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxy butanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonylalcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, and diacetone alcohol; a polyalcohol-based solvent such as ethyleneglycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethyleneglycol, dipropyleneglycol, triethylene glycol, and tripropylene glycol; and a polyalcohol-containing ether-based solvent such as ethyleneglycol monomethylether, ethyleneglycol monoethylether, ethyleneglycol monopropylether, ethyleneglycol monobutylether, ethyleneglycol monohexylether, ethyleneglycol monophenylether, ethyleneglycol mono-2-ethylbutylether, diethyleneglycol monomethylether, diethyleneglycol monoethylether, diethyleneglycol monopropylether, diethyleneglycol monobutylether, diethyleneglycol monohexyl ether, diethylene glycol dimethylether, propylene glycol monomethylether, propylene glycol dimethylether, propylene glycol monoethylether, propylene glycol monopropylether, propylene glycol monobutylether, dipropyleneglycol monomethylether, dipropyleneglycol monoethylether, and dipropyleneglycol monopropylether.

Examples of the ether-based solvents may include: a dialkylether-based solvent such as diethylether, dipropylether, and dibutylether; a cyclic ether-based solvent such as tetrahydrofuran and tetrahydropyran; and an aromatic ring-containing ether-based solvent such as diphenylether and anisole.

Examples of the ketone-based solvents may include: a chain-shaped ketone-based solvent such as acetone, methylethylketone, methyl-n-propylketone, methyl-n-butylketone, methyl-n-pentylketone, diethylketone, methylisobutylketone, 2-heptanone, ethyl-n-butylketone, methyl-n-hexylketone, diisobutylketone, and trimethylnonanone; a cyclic ketone-based solvent such as cyclopentanone, cyclo hexanone, cycloheptanone, cyclooctanone, and methylcyclohexanone; and 2,4-pentanedione, acetonylacetone, and acetophenone.

Examples of the amide-based solvents may include: a cyclic amide-based solvent such as N,N′-dimethylimidazolidinone and N-methyl-2-pyrrolidone; and a chain-shaped amide-based solvent such as N-methylformamide, N,N-dimethylformamide, N,N-diethylformamide, acetamide, N-methylacetamide, N,N-dimethylacetamide, and N-methylpropyoneamide.

Examples of the ester-based solvents may include: an acetate ester-based solvent such as methyl acetate, ethyl acetate, n-propyl acetate, isopropyl acetate, n-butyl acetate, isobutyl acetate, sec-butyl acetate, T-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, and n-nonyl acetate; a polyalcohol-containing ethercarboxylate-based solvent such as ethyleneglycol monomethylether acetate, ethyleneglycol monoethylether acetate, diethyleneglycol monomethylether acetate, diethyleneglycol monoethylether acetate, diethyleneglycol mono-n-butyl ether acetate, propylene glycol monomethylether acetate (PGMEA), propylene glycol monoethylether acetate, propylene glycol monopropylether acetate, propylene glycol monobutylether acetate, dipropylene glycol monomethylether acetate, and dipropylene glycol monoethylether acetate; a lactone-based solvent such as γ-butyrolactone and δ-valerolactone; a carbonate-based solvent such as dimethyl carbonate, diethyl carbonate, ethylene carbonate, and propylene carbonate; a lactate ester-based solvent such as methyl lactate, ethyl lactate, n-butyl lactate, and n-amyl lactate; and glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, and diethyl phthalate.

Examples of the sulfoxide-based solvents may include dimethyl sulfoxide and diethyl sulfoxide.

Examples of the hydrocarbon-based solvents may include: an aliphatic hydrocarbon-based solvent such as n-pentane, isopentane, n-hexane, isohexane, n-heptane, isoheptane, 2,2,4-trimethyl pentane, n-octane, isooctane, cyclohexane, and methylcyclohexane; and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, and n-amylnaphthalene.

Specifically, the organic solvent may be selected from the alcohol-based solvent, the amide-based solvent, the ester-based solvent, the sulfoxide-based solvent, and any combination thereof. More specifically, the solvent may be selected from propylene glycol monomethylether, propylene glycol monoethylether, propylene glycol monomethylether acetate, N-methyl-2-pyrrolidone, N,N-dimethylacetamide, ethyl lactate, dimethylsulfoxide, and any combination thereof.

The organic solvent may be included in an amount of about 200 parts by weight to about 5,000 parts by weight, specifically, about 400 parts by weight to about 3,000 parts by weight based on 100 parts by weight of the polymer.

### <Optional Components>

The resist composition may further include, if required, an acid generator, a quencher, a dissolution enhancer, a dissolution inhibitor, a surfactant, a crosslinking agent, a leveling agent, a colorant, or any combination thereof.

The resist composition may further include an acid generator to improve developability, or the like. The acid generator may be an ionic acid generator and a non-ionic acid generator.

Examples of the acid generator may include p-toluenesulfonic acid, trifluoromethanesulfonic acid, pyridinium-p-toluenesulfonate, pyridiniumtrifluoromethanesulfonate, salicylic acid, 5-sulfosalicylic acid, camphorsulfonic acid, 4-chlorobenzenesulfonic acid, 4-phenolsulfonic acid, 4-phenolsulfonic acid methyl, benzenedisulfonic acid, 1-naphthalenesulfonic acid, citric acid, benzoic acid, hydroxybenzoic acid, n-tosyloxyphthalimide, N-hydroxynaphthalimide triflate, O-tosylacetophenoneoxime, N-trifluoromethylsulfonyloxyphthalimide, N-(trifluoromethylsulfonyloxy)-1,8-naphthalimide, N-(trifluoromethylsulfonyloxy)bicyclo[2.2.1]hept-5-ene-2,3-dicarboxyimide, N-(nonafluoro-n-butylsulfonyloxy)bicyclo[2.2.1]hept-5-ene-2,3-dicarboxyimide, N-(perfluoro-n-octylsuofonyloxy)-1,8-naphthalimid, N-(perfluoro-n-octylsulfonyloxy)bicyclo[2.2.1]hept-5-ene-2,3-dicarboxyimide, N-(2-bicyclo [2.2.1]hept-2-yl-1,1,2,2-tetrafluoroethylsulfonyloxy)bicyclo[2.2.1]hept-5-ene-2,3-dicarboxyimide, N-(2-(3-tetracyclo [4.4.0.1^{2,5}. 1^{7,10}]dodecanyl)-1,1-difluoroethylsulfonyloxy)bicyclo [2.2.1]hept-5-ene-2,3-dicarboxyimide, N-(camphosulfonyloxy)bicyclo[2.2.1]hept-5-ene-2,3-dicarboxyimide or any combination thereof, but are not limited thereto.

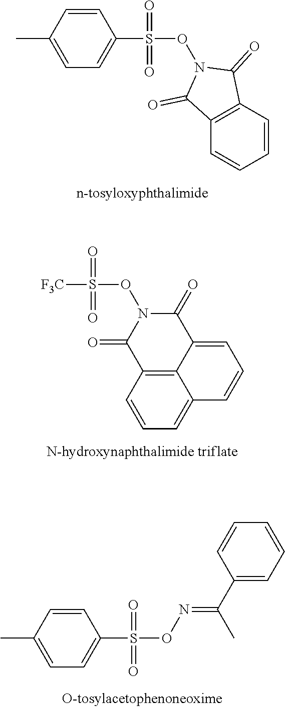 [SMILES: Cc1ccc(S(=O)(=O)ON2C(=O)c3ccccc3C2=O)cc1 ; O=C1c2cccc3cccc(c23)C(=O)N1OS(=O)(=O)C(F)(F)F ; C/C(=N\OS(=O)(=O)c1ccc(C)cc1)c1ccccc1]

Alternatively, the acid generator may be represented by Formula 7 below.

### <Formula 7>

B₇₁⁺ A₇₁⁻

In Formula 7,
B₇₁⁺ is represented by Formula 7A below, A₇₁⁻ is represented by one of Formulae 7B to 7D below, and
B₇₁⁺ may optionally be linked to A₇₁⁻ by a carbon-carbon covalent bond.

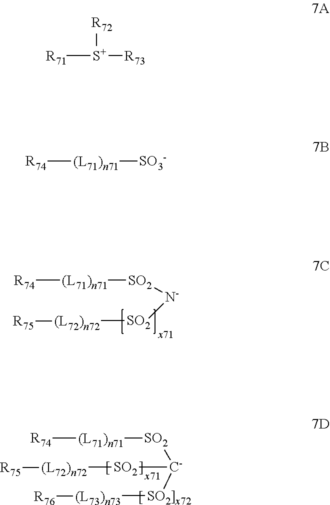

In Formulae 7A to 7D,
L₇₁ to L₇₃ are each independently a single bond or CRR′,
R and R′ are each independently hydrogen, deuterium, a halogen atom, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n71 to n73 are each independently 1, 2, or 3,
x71 and x72 are each independently 0 or 1,
R₇₁ and R₇₃ are each independently a linear, branched, or cyclic C₁-C₃₀ monovalent hydrocarbon group optionally including a heteroatom;
among R₇₁ to R₇₃, two adjacent ones may optionally bind to each other to form a condensed ring, and
R₇₄ to R₇₆ are each independently hydrogen; a halogen atom; or a linear, branched, or cyclic C₁-C₃₀ monovalent hydrocarbon group optionally including a heteroatom.

For example, in Formula 7, B₇₁⁺ may be represented by Formula 7A and A₇₁⁻ may be represented by Formula 7B. Specifically, in Formula 7A, R₇₁ to R₇₃ may be each independently a phenyl group.

An example of the acid generator may be a compound shown below.

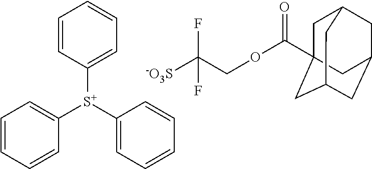

The acid generator may be included in an amount of about 0.01 parts by weight to about 30 parts by weight, about 0.05 parts by weight to about 20 parts by weight, or about 0.1 parts by weight to about 10 parts by weight based on 100 parts by weight of the polycarboxylate compound. In the case where the above-described ranges are satisfied, an appropriate resolution may be obtained, and problems related to particles of foreign matter after development or during stripping may be reduced.

The resist composition may further include a quencher to improve developability, and the like. The quencher may be a salt generating an acid with a lower acidity than an acid generated from the acid generator.

The quencher may include an ammonium salt, a sulfonium salt, an iodonium salt, and any combination thereof.

In an embodiment, the quencher may be represented by Formula 8 below.

### <Formula 8>

Bg₈₁⁺ A₈₁⁻

In Formula 8,
B₈₁⁺ is represented by one of Formulae 8A to 8C below, and A₈₁⁻ is represented by one of Formulae 8D to 8F below, and
B₈₁⁺ may optionally be linked to A₈₁⁻ by a carbon-carbon covalent bond.

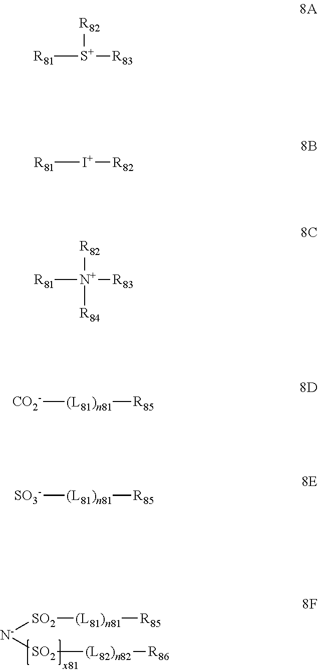

In Formulae 8A to 8F,
L₈₁ and L₈₂ are each independently a single bond or CRR′,
R and R′ are each independently hydrogen, deuterium, a halogen atom, a cyano group, a hydroxyl group, a C₁-C₃₀ alkyl group, a C₁-C₂₀ halogenated alkyl group, a C₁-C₃₀ alkoxy group, a C₃-C₃₀ cycloalkyl group, or a C₃-C₃₀ cycloalkoxy group,
n81 and n82 are each independently 1, 2 or 3,
x81 is 0 or 1,
R₈₁ to R₈₄ are each independently a linear, branched, or cyclic C₁-C₃₀ monovalent hydrocarbon group,
among R₈₁ to R₈₄, two adjacent ones may optionally bind to each other to form a ring, and
R₈₅ and R₈₆ are each independently hydrogen; a halogen atom; or a linear, branched, or cyclic C₁-C₃₀ monovalent hydrocarbon group optionally including a heteroatom.

For example, the quencher may be a compound shown below:

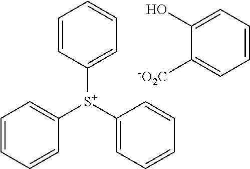

Th quencher may be included in an amount of 0.01 parts by weight to 30 parts by weight, 0.05 parts by weight to 20 parts by weight, or 0.1 parts by weight to 10 parts by weight based on 100 parts by weight of the polycarboxylate compound. In the case where the above-described ranges are satisfied, an appropriate resolution may be obtained, and problems related to particles of foreign matter after development or during stripping may be reduced.

The quencher may be used alone or any combination of two or more different quenchers may also be used.

The resist composition may further include a dissolution inhibitor to improve developability, and the like. The dissolution inhibitor may include a phenolphthalein derivatives, a fluorescein derivatives, or any combination thereof. Examples of the dissolution inhibitor include compounds represented by Formulae I-1 to I-3 below.

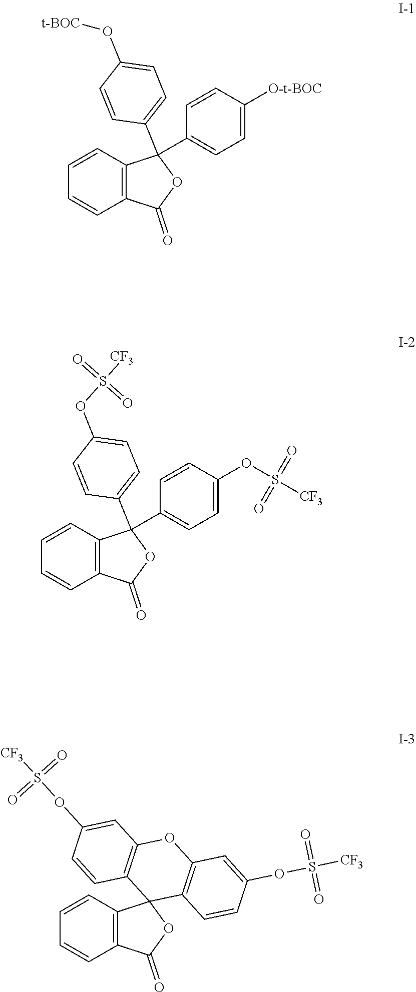

The resist composition may further include a surfactant to improve coatability, developability, and the like. Examples of the surfactant may include a nonioinc surfactant such as polyoxyethylene lauryl ether, polyoxyethylene stearyl ether, polyoxyethyleneoleyl ether, polyoxyethylene n-octylphenyl ether, polyoxyethylene n-nonylphenyl ether, polyethyleneglycol dilaurate, and polyethyleneglycol distearate. Any commercially available product or a synthetic product may be used as the surfactant. Examples of the commercially available product may include KP341 (manufactured by Shin-Etsu Chemical Co., Ltd.), Polyflow No. 75 and Polyflow No. 95 (manufactured by Kyoeisha Chemical Co., Ltd.), Eftop EF301, Eftop EF303, and Eftop EF352 (manufactured by Mitsubishi Materials Electronic Chemicals Co., Ltd.), MEGAFACE® F171, MEGAFACE F173, R40, R41, and R43 (manufactured by DIC Corporation), Fluorad® FC430, Fluorad FC431 (manufactured by 3M Co., Ltd.), AsahiGuard AG710 (manufactured by AGC Co., Ltd.), and Surflon® S-382, Surflon SC-101, Surflon SC-102, Surflon SC-103, Surflon SC-104, Surflon SC-105, and Surflon SC-106 (manufactured by AGC Seimi Chemical Co., Ltd).

The surfactant may be included in an amount of about 0 parts by weight to about 20 parts by weight based on 100 parts by weight of the polymer. The surfactant may be used alone or any mixture of two or more different surfactants may also be used.

A method of preparing the resist composition is not particularly limited, and any method of mixing the polymer and optional components added as occasion demands in an organic solvent may also be used. Temperature or time in the mixing is not particularly limited.

If necessary, filtration may be performed after the mixing.

### [Method of Forming Pattern]

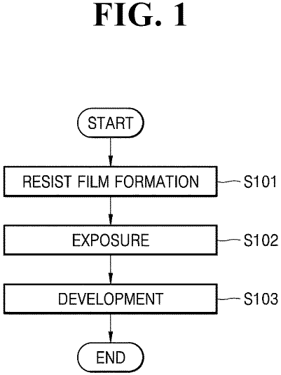

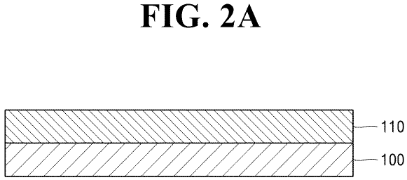

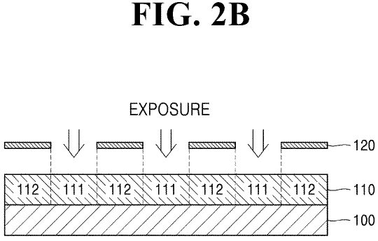

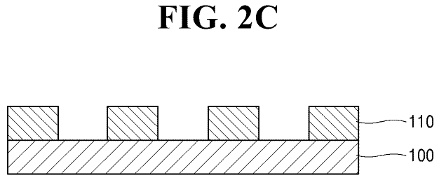

Hereinafter, a method of forming a pattern according to embodiments will be described in more detail with reference to FIG. 1 and FIGS. 2A to 2C. FIG. 1 is a flowchart illustrating a method of forming a pattern according to an embodiment. FIGS. 2A to 2C are side cross-sectional views illustrating a method of forming a pattern according to an embodiment. Hereinafter, a method of forming a pattern using a positive resist composition will be described by way of example, but the embodiment is not limited thereto.

Referring to FIG. 1, a method of forming a pattern includes forming a resist film by applying a resist composition to a substrate (S101), exposing at least one portion of the resist film to high-energy rays (S102), and developing the exposed resist film by using a developer (S103). These processes may be omitted or may be performed in a different order, if necessary.

First, a substrate 100 is prepared. The substrate 100 may be a semiconductor substrate such as a silicon substrate and a germanium substrate, or may be formed of glass, quartz, ceramic, copper, or the like. In some embodiments, the substrate 100 may include Group 3-5 compounds, such as GaP, GaAs, and GaSb.

A resist film 110 may be formed on the substrate 100 by applying the resist composition thereto to a desired thickness using a coating method. If necessary, the resist film 110 may be heated (pre-baked (PB or post-annealing baked (PAB)) to remove the organic solvent remaining in the resist film 110.

As the coating method, spin coating, dipping, roller coating, or other common coating methods may be used. Among them, spin coating may particularly be used. The resist film 110 having a desired thickness may be formed by adjusting viscosity, concentration, and/or spin speed of the resist composition. Specifically, the resist film 110 may have a thickness of 10 nm to 300 nm. More specifically, the resist film 110 may have a thickness of 30 nm to 200 nm.

A lower limit of a pre-baking temperature may be 60° C. or higher, specifically, 80° C. or higher. In addition, an upper limit of the pre-baking temperature may be 150° C. or lower, specifically, 140° C. or lower. A lower limit of a pre-baking time may be 5 seconds or more, specifically, 10 seconds or more. An upper limit of the pre-baking time may be 600 seconds or less, specifically, 300 seconds or less.

Before applying the resist composition to the substrate 100, a film to be etched (not shown) may be formed on the substrate 100. The film to be etched may refer to a film onto which an image is transferred from a resist pattern to be converted into a pattern. In an embodiment, the film to be etched may be formed to include, for example, an insulating material such as a silicon oxide, a silicon nitride, and a silicon oxynitride. In some embodiments, the film to be etched may be formed to include a conductive material such as a metal, a metal nitride, a metal silicide, and a metal silicide nitride film. In some embodiments, the film to be etched may be formed to include a semiconductor material such as polysilicon.

In an embodiment, an anti-reflection film may further be formed on the substrate 100 to maximize efficiency of the resist. The anti-reflection film may be an organic or inorganic anti-reflection film.

In an embodiment, a protective film may further be formed on the resist film 110 to reduce effects of alkaline impurities included during a process. In addition, in the case of performing immersion lithography, a protective film for immersion lithography may be formed on the resist film 110 to avoid direct contact between an immersion medium and the resist film 110.

Subsequently, at least one portion of the resist film 110 may be exposed to high-energy rays. For example, high-energy rays having passed through a mask 120 may reach at least one portion of the resist film 110. Therefore, the resist film 110 may have exposed regions 111 and unexposed regions 112.

The exposure to light is performed by emitting high-energy rays through a mask having a particular pattern using a liquid such as water as a medium, if necessary. Examples of the high-energy rays may include electromagnetic waves such as ultraviolet rays, deep ultraviolet rays, extreme ultraviolet (EUV) rays (wavelength of 13.5 nm), X-rays, and γ-rays; and charged particle beams such as electron beams and a particle beams. Irradiation of these high-energy rays may be collectively referred to as “exposure”.

Various light sources may be used for the exposure. For example, a light source emitting laser beams in the UV range, such as a KrF excimer laser (wavelength of 248 nm), an ArF excimer laser (wavelength of 193 nm), and an F₂ excimer laser (wavelength of 157 nm), a light source emitting harmonic laser beams in the far ultraviolet or vacuum ultraviolet range by converting wavelengths of laser beams received from a solid laser light source (YAG or semiconductor laser), and a light source emitting electron beams or EUVs may be used. During exposure, a mask corresponding to a desired pattern is commonly used. However, in the case of using electron beams as a light source for exposure, exposure may be directly performed without using a mask.

An integral dose of the high-energy rays may be 2000 mJ/cm² or less, specifically, 500 mJ/cm² or less, in the case of using extreme ultraviolet rays as the high-energy rays. In addition, in the case of using electron beams as the high-energy rays, the integral dose may be 5000 μ° C./cm² or less, specifically, 1000 μC/cm² or less.

Although not limited to a particular theory, as the main chain of the polymer is decomposed (chain-scission) and a part of the side chain of the polymer (e.g., photo-degradable groups) is deprotected in the exposed region 111 by light exposure, the molecular weight of the polymer decreases, and accordingly solubility and/or dissolution rate of the polymer in a developer, particularly, a alkaline developer may increase.

Also, post exposure baking (PEB) may be performed after exposure. A lower limit of a PEB temperature may be 50° C. or higher, specifically, 80° C. or higher. An upper limit of the PEB temperature may be 180° C. or lower, specifically, 130° C. or lower. A lower limit of a PEB time may be 5 seconds or more, specifically, 10 seconds or more. An upper limit of the PEB time may be 600 seconds of less, specifically, 300 seconds or less.

The exposed resist film 110 may be developed using a developer. The exposed regions 111 may be washed away by the developer, the unexposed regions 112 may remain without being washed by the developer.

As the developer, an alkaline developer, a developer including an organic solvent (hereinafter, referred to as “organic developer”), and the like may be used. A developing method may be dipping, puddling, spraying, dynamic approach, or the like. A developing temperature may be, for example, from 5° C. to 60° C., and a developing time may be, for example, from 5 seconds to 300 seconds.

Examples of the alkaline developer may include an alkaline aqueous solution including at least one alkaline compound dissolved therein such as sodium hydroxide, potassium hydroxide, sodium carbonate, sodium silicate, sodium metasilicate, aqueous ammonia, ethylamine, n-propylamine, diethylamine, di-n-propyl amine, triethylamine, methyldiethylamine, ethyldimethylamine, triethanolamine, tetramethyl ammonium hydroxide (TMAH), pyrrole, piperidine, choline, 1,8-diazabicyclo [5.4.0]-7-undecene (DBU), and 1,5-diazabicyclo [4.3.0]-5-nonene (DBN). The alkaline developer may further include a surfactant.

A lower limit of an amount of the alkaline compound contained in the alkaline developer may be 0.1 mass % or more, specifically, 0.5 mass % or more, more specifically, 1 mass % or more. In addition, an upper limit of the amount of the alkaline compound contained in the alkaline developer may be 20 mass % or less, specifically, 10 mass % or less, more specifically, 5 mass % or less.

After development, the resist pattern may be washed with ultrapure water, and then, water remaining on the substrate and the pattern may be removed.

For example, the organic solvent contained in the organic developer may be the same as those described above in the <Organic Solvent> section of the [Resist Composition].

In the organic developer, a lower limit of the amount of the organic solvent may be 80 wt % or more, specifically, 90 wt % or more, more specifically, 95 wt % or more, particularly, 99 wt % or more.

The organic developer may include a surfactant. In addition, the organic developer may include a trace amount of moisture. In addition, development may be stopped during developing by replacing the organic developer with a different type of solvent.

The resist pattern may further be washed after the developing. Ultrapure water, a ringing solution, and the like may be used as a washing solution. The rinsing solution is not particularly limited as long as the resist pattern is not dissolved therein, and any solution including a common organic solvent may be used. For example, the rinsing solution may be an alcohol-based solvent or an ester-based solvent. After washing, the rinsing solution remaining on the substrate and the pattern may be removed. Also, in the case of using ultrapure water, water remaining on the substrate and the pattern may be removed.

In addition, the developer may be used alone or any combination of two or more different developers may also be used.

After the resist pattern is formed as described above, a pattered wiring substrate may be obtained by etching. Any etching methods well known in the art such as dry etching using plasma gas, and wet etching using an alkaline solution, a copper (II) chloride solution, or a ferric chloride solution may be used.

After forming the resist pattern, plating may be performed. Although a plating method is not particularly limited, for example, copper plating, solder plating, nickel plating, and gold plating may be used.

The resist pattern remaining after etching may be stripped off using an organic solvent. Examples of the organic solvent may be, but are not limited to, propylene glycol monomethylether acetate (PGMEA), propylene glycol monomethylether (PGME), and ethyl lactate (EL). Although a peeling method is not particularly limited, for example, immersing and spraying may be used. In addition, a wiring substrate on which the resist pattern is formed may be a multi-layered wiring substrate or may have a small-diameter through hole.

In an embodiment, the wiring substrate may be formed by a method including forming a resist pattern, depositing a metal thereon in a vacuum, and melting the resist pattern using a solution, e.g., a lift-off method.

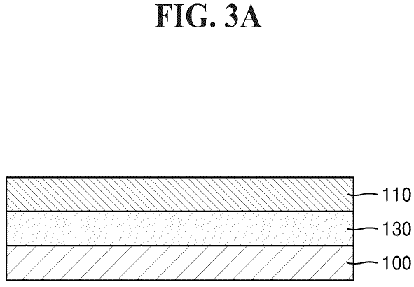

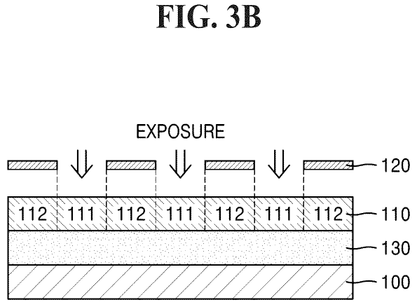

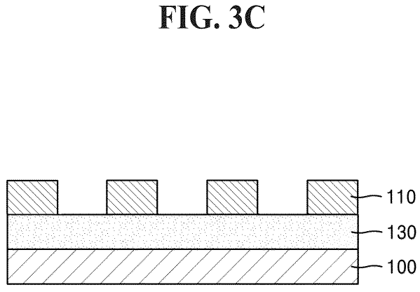

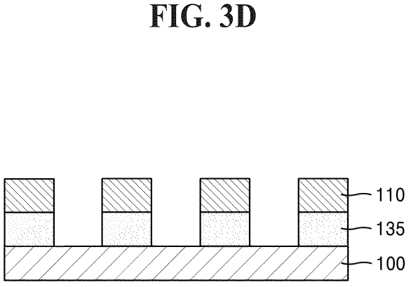

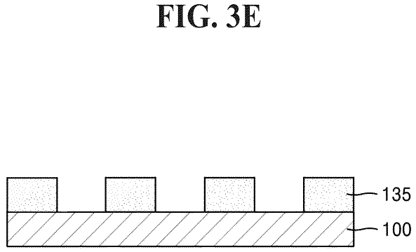

FIGS. 3A to 3E are side cross-sectional views illustrating a method of forming a patterned structure according to an embodiment.

Referring to FIG. 3A, a material layer 130 may be formed on the substrate 100 before forming a resist film 110 on the substrate 100. The resist film 110 may be formed on top of the material layer 130. The material layer 130 may include an insulating material (e.g., silicon oxide, silicon nitride), a semiconductor material (e.g., silicon), a metal (e.g., copper). In some embodiments, the material layer 130 may be a multi-layer structure. A material of the material layer 130 may be different than a material of the substrate 100.

Referring to FIG. 3B, the resist film 110 may undergo a pre-exposure bake process and may be exposed with high energy rays through a mask 120, after which the resist film 110 may include exposed regions 111 and unexposed regions 112.

Referring to FIG. 3C, the exposed resist film 110 may be developed using a developer (e.g., developing solution). The exposed regions 111 may be washed away by the developer, whereas the unexposed regions 112 may remain without being washed away by the developer.

Referring to FIG. 3D, exposed areas of the material layer 130 may be etched using the resist pattern 110 as a mask to form a material pattern 135 on the substrate 100.

Referring to FIG. 3E, the resist pattern 110 may be removed.

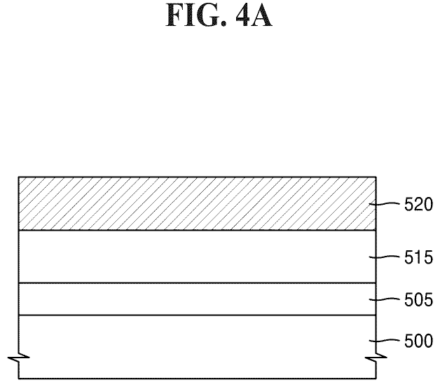

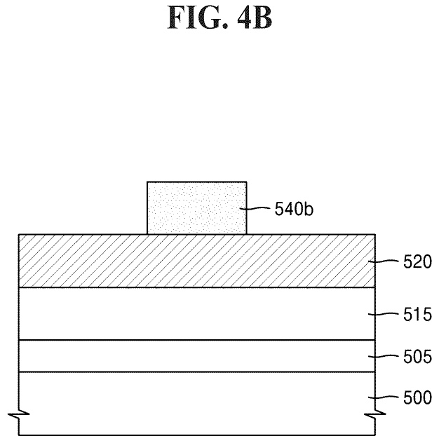

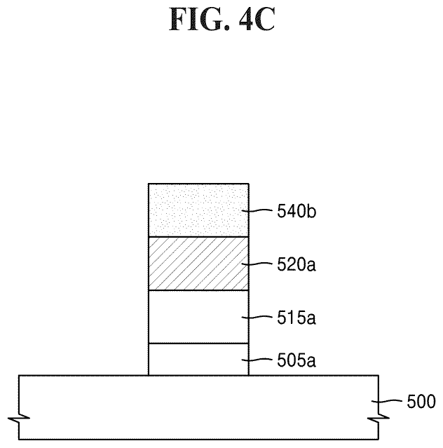

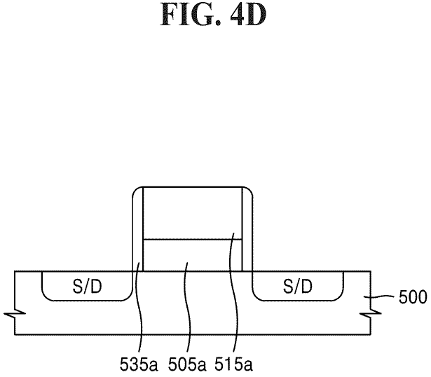

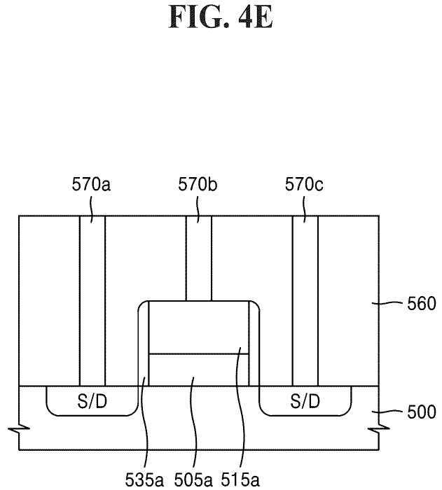

FIGS. 4A to 4E are side cross-sectional views illustrating a method of forming a semiconductor device according to an embodiment.

Referring to FIG. 4A, a gate dielectric 505 (e.g., silicon oxide) may be formed on a substrate 500. The substrate 500 may be a semiconductor substrate, such as a silicon substrate, but is not limited thereto. A gate layer 515 (e.g., doped polysilicon) may be formed on the gate dielectric 505. A hardmask layer 520 may be formed on the gate layer 515.

Referring to FIG. 4B, a resist pattern 540b may be formed on the hardmask layer 520. The resist pattern 540b may be formed using a resist composition according to example embodiments.

Referring to FIG. 4C, the hardmask layer 520, gate layer 515, and the gate dielectric 505 may be etched to form a hardmask pattern 520a, a gate electrode pattern 515a, and a gate dielectric pattern 505a. The resist pattern 540b and hardmask pattern 520a may be removed after the gate electrode pattern 515a and gate dielectric pattern 505a are formed. Alternatively, the resist pattern 540b may be removed and the hardmask pattern 520a may remain after the gate electrode pattern 515a and gate dielectric pattern 505a are formed.

Referring to FIG. 4D, a spacer layer may be formed over the gate electrode pattern 515a and the gate dielectric pattern 505a. The spacer layer may be formed using a deposition process (e.g., CVD). The spacer layer may be etched to form spacers 535a (e.g., silicon nitride) on sidewalls of the gate electrode pattern 515a and the gate dielectric pattern 505a. After forming the spacers 535a, ions may be implanted into the substrate 500 to form source/drain impurity regions S/D.

Referring to FIG. 4E, an interlayer insulating layer 560 (e.g., oxide) may be formed on the substrate 500 to cover the gate electrode pattern 515a, gate dielectric pattern 505a, and spacers 535a. Then, electrical contacts 570a, 570b, and 570c may be formed in the interlayer insulating layer 560 to connect to the gate electrode 515a and the S/D regions. The electrical contacts may be formed of a conductive material (e.g., metal). Although not illustrated, a barrier layer may be formed between sidewalls of the interlayer insulating layer 560 and the electrical contacts 570a, 570b, and 570c. While FIGS. 4A to 4E illustrate an example of forming a transistor, inventive concepts are not limited thereto. A resist composition according to one or more embodiments may be used in a patterning process to form other types of semiconductor devices.

Hereinafter, the disclosure will be described in more detail according to the following examples and comparative examples. However, the following examples are merely presented to convey inventive concepts of the disclosure, and the scope of the disclosure is not limited thereto.

### EXAMPLES

### Synthesis Example 1: Synthesis of Monomer A-1

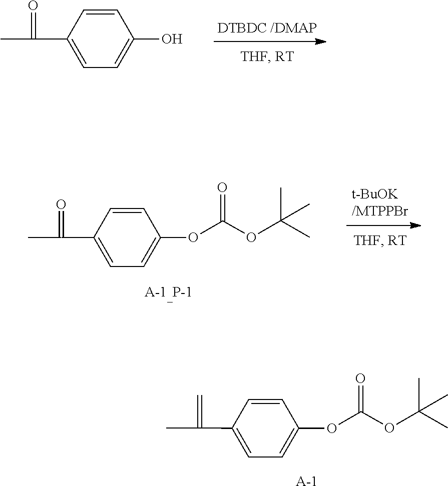

### (1) Synthesis of Compound A-1_P-1

In a nitrogen atmosphere, 4-hydroxyacetophenone (10 g, 73.5 mmol) was mixed with tetrahydrofuran (THF, 150 ml), trimethylamine (TEA) (15.4 ml, 110 mmol), and 4-dimethylaminopyridine (DMAP) (1.8 g, 14.7 mmol), and the reaction solution was cooled to 0° C. Di-tert-butyl dicarbonate (DTBDC) (18.4 g, 84.5 mmol) dissolved in tetrahydrofuran(THF) (20 ml) was slowly added to the solution, followed by stirring at room temperature for 16 hours. Subsequently, an organic layer obtained by extraction using 300 ml of water and 400 ml of ethyl acetate (EA) was rinsed with a saturated NaCl aqueous solution and dried with MgSO₄, followed by filtration. A filtrate obtained therefrom was depressurized, and a residue obtained therefrom was separated and purified by silica gel column chromatography (as a developing solvent, ethyl acetate: n-hexane=10:90 (volume ratio)) to obtain 16.81 g of Compound A-1_P-1 (yield: 65%). ¹H-NMR data of the produced compound was identified.

¹H-NMR (500 MHz, CDCl₃-d₁) δ 8.95 (d, 2H), 7.23 (d, 2H), 2.54 (s, 3H), 1.52 (s, 9H).

### (2) Synthesis of Monomer A-1

A solution of methyltriphenylphosphonium bromide (24.9 g, 69.8 mmol) dissolved in tetrahydrofuran (THF, 100 ml) was cooled to 0° C. in a nitrogen atmosphere. A potassium tert-butoxide solution (1M in THF) (70 mL, 69.8 mmol) was slowly added to the solution. The solution was further stirred at 0° C. for 4 hours, and a solution of the synthetic Compound A-1_P-1 (15 g, 63.5 mmol) dissolved in tetrahydrofuran (THF) (50 ml) was slowly added thereto. The reaction mixture was further stirred at room temperature for 12 hours. The mixed solution was subjected to filtration using Celite and concentrated, followed by extraction with 100 ml of water and 300 ml of ethyl acetate (EA). An organic layer obtained therefrom was rinsed with a saturated NaCl aqueous solution and dried with MgSO₄, followed by filtration. A filtrate obtained therefrom was depressurized and a residue obtained therefrom was separated and purified by silica gel column chromatography (ethyl acetate: n-hexane=5:95 (volume ratio)) to obtain 10.8 g of Monomer A-1 (yield: 73%). ¹H-NMR data of the produced compound was identified.

¹H-NMR (500 MHz, CDCl₃-d₁) δ 7.48 (d, 2H), 7.15 (d, 2H), 5.35 (s, 1H), 5.09 (s, 1H), 2.15 (s, 3H), 1.58 (s, 9H).

### Synthesis Example 2: Synthesis of Monomer A-2

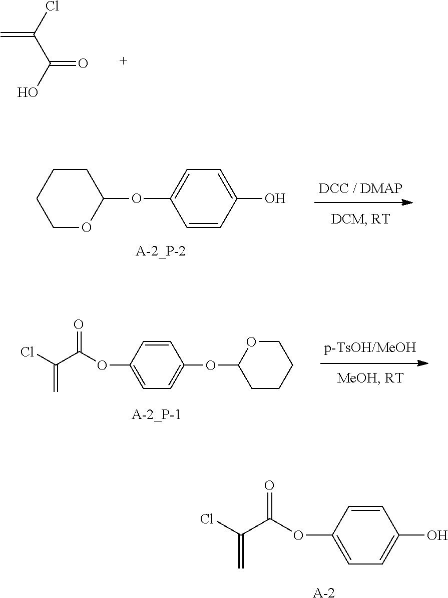

### (1) Synthesis of Compound A-2_P-1

In a nitrogen atmosphere, 2-chloroacrylic acid (3.46 g, 32.4 mmol), 4-(tetrahydropyran-2-yloxy)phenol (A-2-P-2) (6 g, 30.9 mmol), and 4-dimethylaminopyridine (DMAP) (0.14 g, 1.1 mmol) were mixed with dichloromethane (DCM) (45 ml) and the mixture was cooled to 0° C. N,N′-dicyclohexylcarbodiimide (DCC) (7.7 g, 37.1 mmol) dissolved in dichloromethane (DCM) (45 ml) was slowly added to the solution, and the reaction mixture was additionally stirred at room temperature for 12 hours. After reaction was completed, the formed precipitate was filtered and an organic layer was rinsed with 50 ml of water and a saturated NaCl aqueous solution and dried with MgSO₄, followed by filtration. A filtrate obtained therefrom was depressurized, and a residue obtained therefrom was separated and purified by silica gel column chromatography (ethyl acetate: n-hexane=10:90 (volume ratio)) to obtain of 6.6 g Compound A-2_P-1 (yield: 75%). ¹H-NMR data of the produced compound was identified.

¹H-NMR (500 MHz, CDCl₃-d₁) δ 7.07 (m, 4H), 6.73 (s, 1H), 6.17 (s, 1H), 5.39 (t, 1H), 3.91 (s, 1H), 3.62 (s, 1H), 1.86 (m, 1H), 1.68 (m, 1H), 1.67 (m, 4H).

### (2) Synthesis of Monomer A-2

In a nitrogen atmosphere, Synthetic Compound A-2_P-1 (6.6 g, 6323.3 mmol) and p-toluenesulfonic acid (p-TSA) (0.2 g, 1.0 mmol) were dissolved in 100 ml of methanol and stirred at room temperature for 16 hours. After reaction was completed, the mixture was added to 100 ml of water and subjected to extraction with 300 ml of ethyl acetate (EA). An obtained organic layer was rinsed with water and a saturated NaCl aqueous solution and dried with MgSO₄, followed by filtration. A filtrate obtained therefrom was depressurized, and a residue obtained therefrom was separated and purified by silica gel column chromatography (ethyl acetate: n-hexane=1:5 (volume ratio)) to obtain 4.5 g of Monomer A-2 (yield: 97%). ¹H-NMR data of the produced compound was identified.

¹H-NMR (500 MHz, DMSO-d₆) δ 9.54 (s, 1H), 7.01 (t, 2H), 6.77 (t, 2H), 6.77 (d, 1H), 6.42 (d, 1H).

### Synthesis Example 3: Synthesis of Monomer A-3

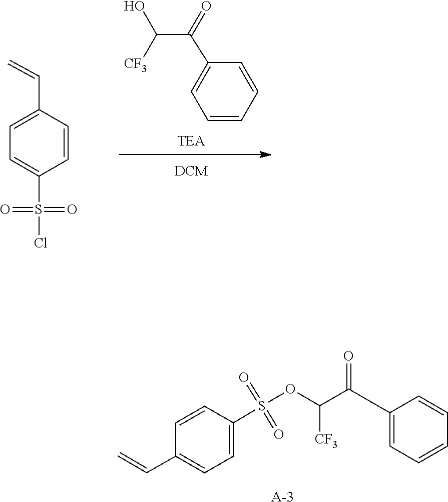 [SMILES: C=Cc1ccc(S(=O)(=O)Cl)cc1 ; O=C(c1ccccc1)C(O)C(F)(F)F ; C=Cc1ccc(S(=O)(=O)OC(C(=O)Cc2ccccc2)C(F)(F)F)cc1 ; "A-3"]

2-hydroxy-2-trifluoromethylacetophenone (10 g, 49 mmol) was mixed with dichloromethane (DCM) (200 ml) and tetraethylamine (TEA) (7.5 ml, 53.9 mmol), and 4-vinylbenzenesulfonyl chloride (7.53 g, 37.2 mmol) was added thereto, followed by stirring at room temperature for 18 hours. Subsequently, an organic layer obtained by extraction using 200 ml of water and 200 ml of DCM was rinsed with a saturated NH₄Cl aqueous solution and a saturated NaCl aqueous solution and dried with MgSO₄, followed by filtration. A filtrate obtained therefrom was depressurized, and a residue obtained therefrom was separated and purified by silica gel column chromatography. A solid obtained therefrom was dissolved in ethylacetate (EA) (5 ml) and n-hexane (n-Hex) (15 ml) and placed in a refrigerator, and then a recrystallized product was filtered to obtain Monomer A-3. ¹H-NMR data of the produced compound was identified.

¹H-NMR (500 MHz, DMSO-d₆) δ 8.14 (d, 2H), 7.94 (d, 2H), 7.75 (t, 3H), 7.59 (t, 2H), 7.10 (q, 1H), 6.84 (dd, 1H), 6.08 (d, 1H), 5.52 (d, 1H).

### Synthesis Example 4: Synthesis of Monomer A-4

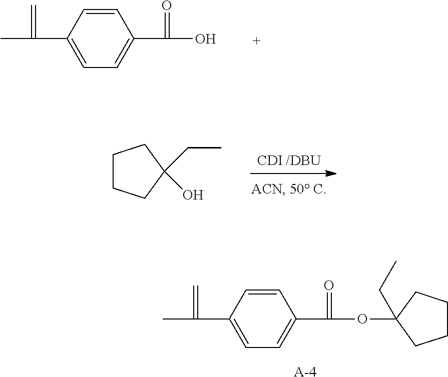

In a nitrogen atmosphere, 4-(prop-1-en-2-yl)benzoic acid (5 g, 31 mmol) was dissolved in acetonitrile (ACN) (100 ml) and the solution was cooled to 0° C. 1,1′-Carbonyldiimidazole (9.0 g, 55.5 mmol) was slowly added to the solution, and the reaction mixture was stirred at 0° C. for 1 hour and further stirred at room temperature for 3 h ours. 1-Ethylcyclopentanol (8.8 g, 77 mmol) was added to the reaction mixture and 1,8-diazabicyclo[5.4.0]undec-7-ene (DBU) (11.5 ml, 77 mmol) was slowly added thereto. The mixture was further subjected to reaction at 50° C. for 16 hours. The reaction was stopped by adding 50 ml of water thereto, and then an organic layer was rinsed with a saturated NaCl aqueous solution and dried with MgSO₄, followed by filtration. A filtrate obtained therefrom was depressurized, and a residue obtained therefrom was separated and purified by silica gel column chromatography (ethyl acetate: n-hexane=1:10 (volume ratio)) to obtain 7.3 g of Monomer A-4 (yield: 91%). The produced compound was identified by ¹H-NMR.

¹H-NMR (500 MHz, CDCl₃-d₁) δ 7.98 (d, 2H), 7.50 (d, 2H), 5.45 (s, 1H), 5.17 (s, 1H), 2.30 (m, 2H), 2.16 (s, 3H), 2.12 (m, 2H), 1.78 (m, 4H), 1.67 (s, 2H), 0.94 (t, 3H).

### Synthesis Example 5: Synthesis of Polymer P-1

Monomer A-1 (1.50 g, 6.4 mmol), Monomer A-2 (1.27 g, 6.4 mmol), and an initiator V601 (0.19 g, 0.64 mmol) were dissolved in a cyclopentanone solvent (2.8 g). After stirring the solution at 60° C. for 6 hours, white solid powder obtained by precipitation in n-hexane was filtered to obtain Polymer P-1 (1.53 g, yield: 55%).

### Synthesis Example 6: Synthesis of Polymer P-2

Polymer P-2 (0.75 g, yield: 43%) was obtained in the same manner as in Synthesis Example 5, except that Monomer A-1 (0.94 g, 4.0 mmol), Monomer A-2 (0.80 g, 4.0 mmol), the initiator V601 (0.12 g, 0.4 mmol), and cyclopentanone (7.0 g) were used.

### Synthesis Example 7: Synthesis of Polymer P-3

Polymer P-3 (1.52 g, yield: 64%) was obtained in the same manner as in Synthesis Example 5, except that Monomer A-1 (1.51 g, 6.5 mmol), Monomer A-2 (0.86 g, 4.3 mmol), the initiator V601 (0.12 g, 0.54 mmol), and cyclopentanone (5.5 g) were used.

### Synthesis Example 8: Synthesis of Polymer P-4

Polymer P-4 (1.84 g, yield: 61%) was obtained in the same manner as in Synthesis Example 5, except that Monomer A-1 (1.50 g, 6.4 mmol), Monomer A-2 (1.02 g, 5.1 mmol), Monomer A-3 (0.47 g, 1.3 mmol), the initiator V601 (0.15 g, 0.64 mmol), and cyclopentanone (7.0 g) were used.

### Synthesis Example 9: Synthesis of Polymer P-5

Polymer P-5 (1.84 g, yield: 61%) was obtained in the same manner as in Synthesis Example 5, except that Monomer A-1 (1.50 g, 6.4 mmol), Monomer A-2 (1.00 g, 5.1 mmol), Monomer A-3 (0.22 g, 0.60 mmol), the initiator V601 (0.14 g, 0.60 mmol), and cyclopentanone (6.4 g) were used.

### Synthesis Example 10: Synthesis of Polymer P-6

Polymer P-6 (1.12 g, yield: 49%) was obtained in the same manner as in Synthesis Example 5, except that Monomer A-4 (1.53 g, 5.9 mmol), Monomer A-2 (0.78 g, 3.9 mmol), the initiator V601 (0.11 g, 0.49 mmol), and cyclopentanone (5.4 g) were used.

### Synthesis Example 11: Synthesis of Polymer P-7

Polymer P-7 (135 g, yield: 72%) was obtained in the same manner as in Synthesis Example 5, except that Monomer A-1 (1.02 g, 4.4 mmol), Monomer A-2 (0.86 g, 4.4 mmol), the initiator V601 (0.10 g, 0.44 mmol), and cyclopentanone (4.4 g) were used.

### Synthesis Example 12: Synthesis of Polymer P-X

Polymer P-X (2.57 g, yield: 77%) was obtained in the same manner as in Synthesis Example 5, except that Monomer B-1 (1.0 g, 8.5 mmol), Monomer B-2 (2.53 g, 8.5 mmol), the initiator V601 (0.19 g, 0.85 mmol), and cyclopentanone (7.8 g) were used.

### Synthesis Example 13: Synthesis of Polymer P-Y

A Polymer P-Y precursor (2.26 g, yield: 70%) was obtained in the same manner as in Synthesis Example 5, except that Monomer B-4 (0.5 g, 4.8 mmol), Monomer B-5 (1.48 g, 6.7 mmol), Monomer B-6 (1.25 g, 7.7 mmol), the initiator V601 (0.22 g, 0.96 mmol), and cyclopentanone (7.5 g) were used.

The obtained precursor was dissolved in a tetrahydrofuran/methanol (1/1, v/v) solution and then deprotection reaction of acetal groups present at the Monomer B-6 site was performed using an ammonia aqueous solution. The reaction solution was reprecipitated in n-hexane to obtain Polymer P-Y. Based on a result of ¹H-NMR analysis, it was confirmed that all acetyl groups were deprotected.

### Synthesis Example 14: Synthesis of Polymer P-Z

A Polymer P-Z precursor (2.18 g, yield: 65%) was obtained in the same manner as in Synthesis Example 5, except that Monomer B-7 (2.0 g, 11.4 mmol), Monomer B-3 (1.37 g, 11.4 mmol), the initiator V601 (0.26 g, 1.14 mmol), and cyclopentanone (7.9 g) were used.

The obtained precursor was dissolved in a tetrahydrofuran/methanol (1/1, v/v) solution and then deprotection reaction of acetal groups present at the Monomer B-7 site was performed using an ammonia aqueous solution. The reaction solution was reprecipitated in n-hexane to obtain Polymer P-Z. Based on a result of ¹H-NMR analysis, it was confirmed that all acetyl groups were deprotected.

Weight average molecular weights and PDIs of the polymers obtained in Synthesis Examples 5 to 14 are shown in Table 2.

TABLE 2

| | | Ratio | Weight average | |
|---|---|---|---|---|
| | | (molar | molecular | |
| Polymer | Monomer | ratio) | weight (Mw) | PDI |
| P-1 | A-1/A-2 | 50/50 | 21.0 k | 3.10 |
| P-2 | A-1/A-2 | 50/50 | 7.4 k | 1.76 |
| P-3 | A-1/A-2 | 60/40 | 17.4 k | 2.15 |
| P-4 | A-1/A-2/A-3 | 50/40/10 | 21.9 k | 2.23 |
| P-5 | A-1/A-2/A-3 | 53/42/5 | 16.7 k | 2.12 |
| P-6 | A-4/A-2 | 60/40 | 9.4 k | 1.63 |
| P-7 | A-1/A-2 | 50/50 | 17.3 k | 2.20 |
| P-X | B-1/B-2 | 50/50 | 13.2 k | 2.61 |
| P-Y | B-4/B-5/B-6 | 25/35/40 | 25.7 k | 1.67 |
| P-Z | B-7/B-3 | 50/50 | 17.1 k | 2.50 |

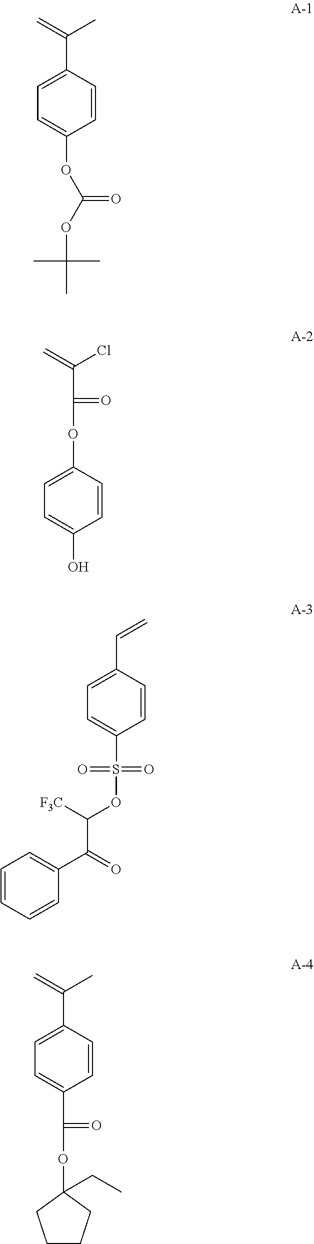 [SMILES: C=C(C)c1ccc(OC(=O)OC(C)(C)C)cc1 ; C=C(Cl)C(=O)Oc1ccc(O)cc1 ; C=Cc1ccc(S(=O)(=O)OC(C(=O)c2ccccc2)C(F)(F)F)cc1 ; C=C(C)c1ccc(C(=O)OC2(CC)CCCC2)cc1]

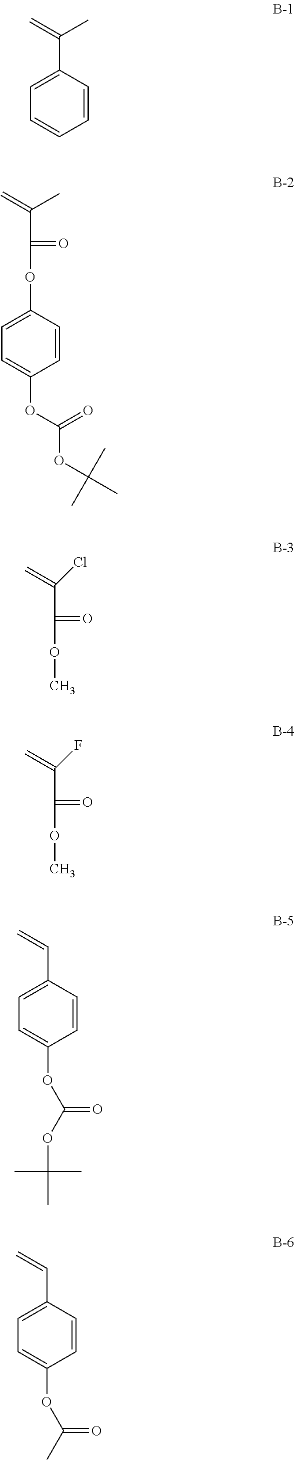

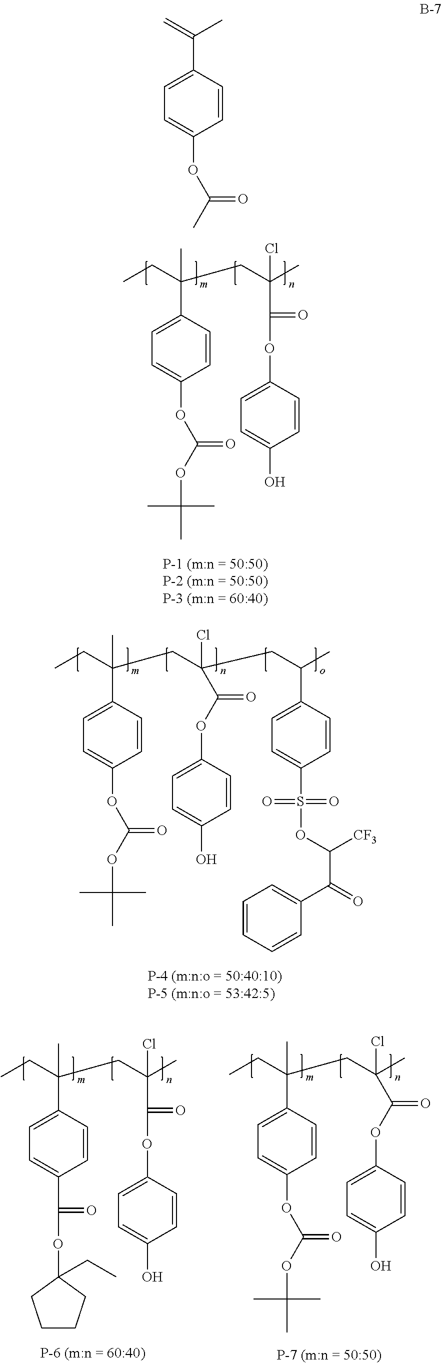

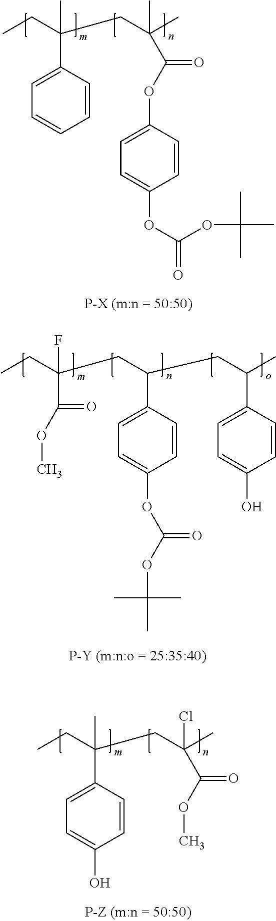

### Evaluation Example 1: Evaluation of Thin Film Development

### (1) Terms

E₀ refers to an exposure dose at a point where a thin film is completely developed (a thickness of the thin film is no longer decreased), and E₁ refers to an exposure dose at a point where development of the thin film is initiated. γ indicating a contrast curve is a value calculated by Equation 1 below.

Equation 1

$$γ = {[ log ( \frac{{E}_{0}}{{E}_{1}} ) ]}^{- 1}$$

### (2) Evaluation of Thin Film Development

The polymers synthesized in Synthesis Examples 5 to 14 were dissolved in a casting solvent of PGME/PGMEA (7/3(w/w)) in 1.5 wt %. In the case of Examples 7 to 10, PAG-1 (23 mmol) and PAG-2 (30 mmol), as acid generators, and/or PDQ(20 mmol), as a quencher, were added thereto based on 100 parts by weight of each of the polymers, followed by filtration by using a 0.2 m separator filter. An HMDS-treated silicon wafer was spin-coated with the casting solution at a speed of 1500 rpm and dried at 110° C. for 1 minute (PAB) to form a thin film. Subsequently, the thin film was exposed to light having a wavelength of 13.5 nm (EUV) at a dose of 0 mJ/cm² to 200 mJ/cm², and optionally, dried (PEB) at 90° C. for 1 minute to prepare a film (wherein PEB was performed only in Examples 4 to 9). The obtained film was immersed in a 2.38 wt % TMAH aqueous solution at 25° C. for 60 seconds, rinsed with water, and naturally dried, and then a thickness of the remaining film was measured using a film thickness measurement instrument (Filmetrics®, F-20) and shown in Table 3 below.

TABLE 3

| | | acid | | | | |
|---|---|---|---|---|---|---|
| Example No. | Polymer | generator | quencher | E₁ | E₀ | γ |
| Example 1 | P-1 | — | — | 27.5 | 58.9 | 3.03 |
| Example 2 | P-2 | — | — | 2.8 | 15.5 | 1.35 |
| Example 3 | P-3 | — | — | 32.4 | 81.0 | 2.51 |
| Example 4 | P-4 | — | — | 30.5 | 46.7 | 5.40 |
| Example 5 | P-5 | — | — | 30.8 | 50.6 | 4.64 |
| Example 6 | P-7 | — | — | 7.3 | 31.0 | 1.59 |
| Example 7 | P-1 | PAG-1 | PDQ | 21.2 | 27.2 | 9.24 |
| Example 8 | P-3 | PAG-1 | PDQ | 18.3 | 23.9 | 8.62 |
| Example 9 | P-6 | PAG-1 | PDQ | 12.3 | 19.5 | 5.00 |
| Example 10 | P-3 | PAG-2 | — | 6.2 | 13.2 | 3.05 |
| Comparative | P-X | — | — | Not developed | | |
| Example 1 | | | | | | |
| Comparative | P-Y | — | — | 41.3 | 115.9 | 2.23 |
| Example 2 | | | | | | |
| Comparative | P-Z | — | — | 38.5 | 102.1 | 2.36 |
| Example 3 | | | | | | |

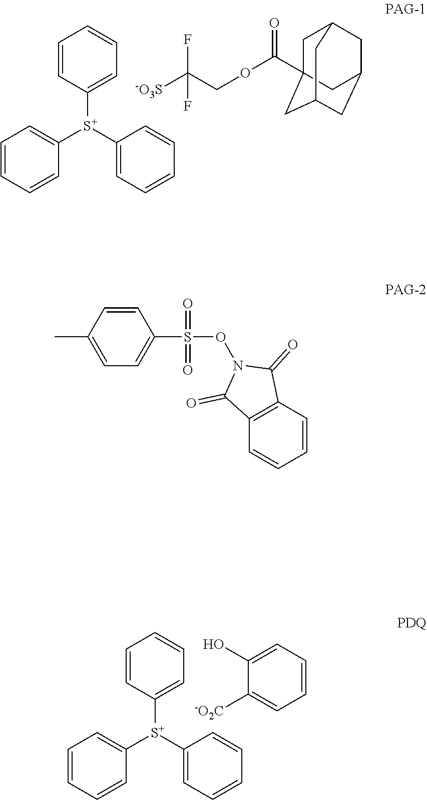

Referring to Table 3, it was confirmed that solubility changed in all of the synthesized polymers after exposure to EUV. In the case of Polymer P-X of Comparative Example 1, a thickness was not changed at all even at a dose of 200 mJ/cm² during developing using an alkaline developer, and thus it was determined that developing did not occur.

Referring to Table 3, it was confirmed that the resist compositions including Polymers P-1 to P-7 according to an embodiment exhibited smaller E₁ and E₀ values than the resist compositions including Polymers P-X to P-Z. Based thereon, it was confirmed that the resist compositions including Polymers P-1 to P-7 had increased photosensitivity compared to the resist compositions including Polymers P-X to P-Z.

According to an embodiment, a polymer having physical properties changing at a low dose, a resist composition including the same, and a method of forming a pattern using the same may be provided.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A polymer comprising:
a first repeating unit represented by Formula 1 below; and
a second repeating unit represented by Formula 2 below, 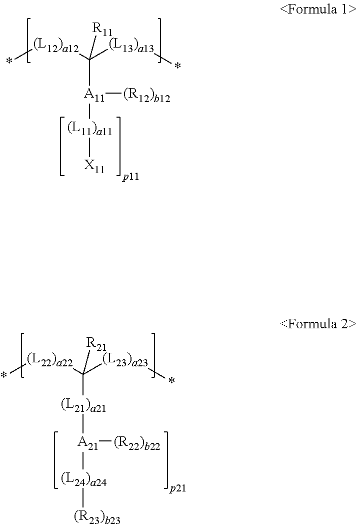
wherein, in Formulae 1 and 2,
L₁₁ to L₁₃ and L₂₁ to L₂₄ are each independently: a single bond; O; S; C(═O); C(═O)O; OC(═O); C(═O)NH; NHC(═O); S(═O); S(═O)₂O; OS(═O)₂; or a linear, branched, or cyclic C₁-C₃₀ divalent hydrocarbon group optionally including a heteroatom,
a11 to a13 and a21 to a24 are each independently an integer from 1 to 4,
A₁₁ and A₂₁ are each independently a C₆-C₃₀ aryl group or a C₁-C₃₀ heteroaryl group,
X₁₁ is a photo-degradable group,
R₁₁ is a halogen atom, or a linear, branched, or cyclic C₁-C₃₀ monovalent hydrocarbon group optionally including a heteroatom,
R₂₁ is a halogen atom, or a linear, branched, or cyclic C₁-C₃₀ monovalent hydrocarbon group substituted with a halogen atom,
R₁₂ and R₂₂ are each independently: hydrogen; deuterium; a halogen atom; a cyano group; a hydroxyl group; an amino group; a carboxylate group; a thiol group; a carbonyl moiety; an ester moiety; a sulfonate moiety; a carbonate moiety; a lactone moiety; a sultone moiety; a carboxylic anhydride moiety; or a linear, branched, or cyclic C₁-C₃₀ monovalent hydrocarbon group optionally including a heteroatom,
R₂₃ is: hydrogen; deuterium; a halogen atom; a cyano group; a hydroxyl group; an amino group; a carboxylate group; a thiol group; a carbonyl moiety; an ester moiety; a sulfonate moiety; a carbonate moiety; a lactone moiety; a sultone moiety; a carboxylic anhydride moiety; a linear, branched, or cyclic C₁-C₃₀ monovalent hydrocarbon group optionally including a heteroatom; or a photo-degradable group,
b12, b22, and b23 are each independently an integer from 1 to 10,
p11 is an integer from 1 to 3,
p21 is an integer from 0 to 4, and
* is a binding site with an adjacent atom.

2. The polymer of claim 1, wherein L₁₁ to L₁₃ and L₂₁ to L₂₄ are each independently: a single bond; O; S; C(═O); C(═O)O; OC(═O); C(═O)NH; NHC(═O); S(═O); S(═O)₂O; OS(═O)₂; a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

3. The polymer of claim 1, wherein A₁₁ and A₂₁ are each independently selected from a phenyl group, a biphenyl group, a terphenyl group, a naphthyl group, a phenanthrenyl group, an anthracenyl group, a triphenylenyl group, a pyrenyl group, a chrysenyl group, a pyrrolyl group, a thiophenyl group, a furanyl group, an imidazolyl group, a pyrazolyl group, a thiazolyl group, an oxazolyl group, a pyridinyl group, a pyrazinyl group, a pyrimidinyl group, a pyridazinyl group, an indolyl group, a quinolinyl group, an isoquinolinyl group, a benzoquinolinyl group, a quinoxalinyl group, a quinazolyl group, and a cinnolinyl group.

4. The polymer of claim 1, wherein A₁₁ and A₂₁ are each independently selected from a phenyl group, a biphenyl group, a terphenyl group, and a naphthyl group.

5. The polymer of claim 1, wherein X₁₁ is a tertiary acyclic alkyl carbon-containing group, a tertiary alicyclic carbon-containing group, acetal, or an O—N bond-containing group.

6. The polymer of claim 1, wherein X₁₁ is represented by one of Formulae 6-1 to 6-14 below: 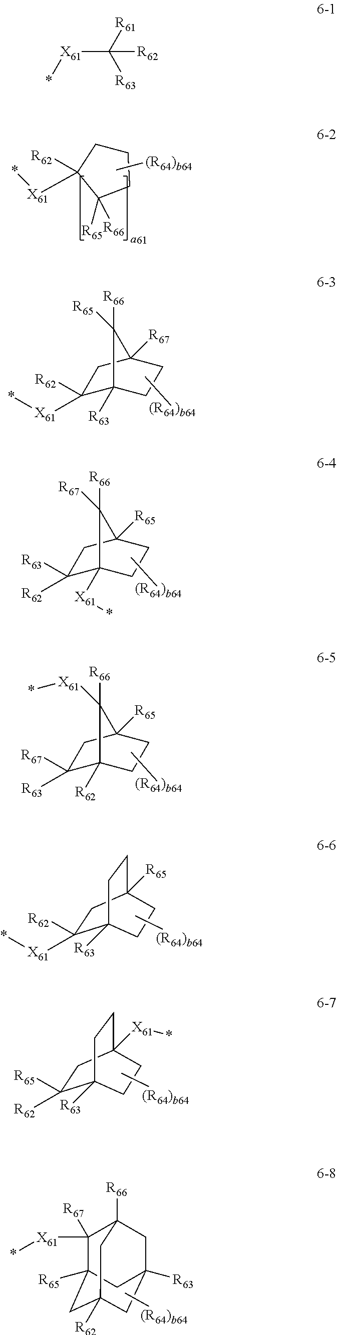 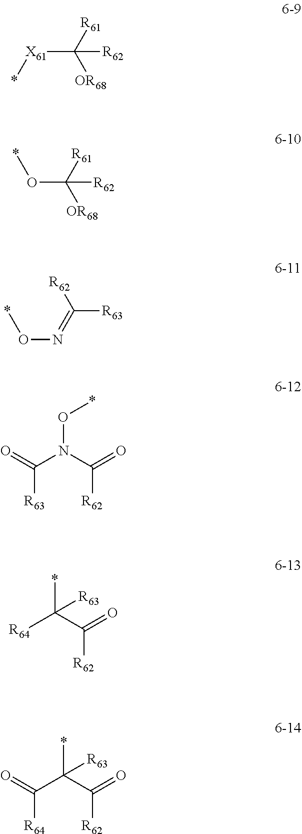
wherein in Formulae 6-1 to 6-14,
X₆₁ is an ester moiety, a carbonate moiety, a carbamate moiety, or a sulfonate moiety;
a61 is an integer from 0 to 6;
R₆₁ and R₆₈ are each independently a linear, branched, or cyclic C₁-C₂₀ monovalent hydrocarbon group optionally including a heteroatom;
R₆₂ to R₆₇ are each independently: hydrogen; deuterium; a halogen atom; a cyano group; a hydroxyl group; an amino group; a carboxylate group; a thiol group; a carbonyl moiety; an ester moiety; a sulfonate moiety; a carbonate moiety; a carbamate moiety; a lactone moiety; a sultone moiety; a carboxylic anhydride moiety; or a linear, branched, or cyclic C₁-C₃₀ monovalent hydrocarbon group optionally including a heteroatom,
among R₆₁ to R₆₈, two adjacent ones optionally bind to each other to form a ring,
b64 is an integer from 1 to 10, and
* is a binding site with an adjacent atom.

7. The polymer of claim 1, wherein
R₁₁ is a halogen atom, a substituted or unsubstituted C₁-C₂₀ alkyl group, or a substituted or unsubstituted C₁-C₂₀ haloalkyl group.

8. The polymer of claim 1, wherein
R₂₁ is a halogen atom or a substituted or unsubstituted C₁-C₂₀ haloalkyl group.

9. The polymer of claim 1, wherein R₁₂ and R₂₂ are each independently selected from: hydrogen; deuterium; a halogen atom; a cyano group; a hydroxyl group; an amino group; a carboxylate group; a thiol group; and a C₁-C₂₀ alkyl group, a C₃-C₂₀ cycloalkyl group, and a C₆-C₂₀ aryl group, each unsubstituted or substituted with deuterium, a halogen atom, a cyano group, a hydroxyl group, an amino group, a carboxylate group, a thiol group, a carbonyl moiety, an ester moiety, a sulfonate moiety, a carbonate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

10. The polymer of claim 1, wherein R₂₃ is selected from: a photo-degradable group; hydrogen; deuterium; a halogen atom; a cyano group; a hydroxyl group; an amino group; a carboxylate group; a thiol group; and a C₁-C₂₀ alkyl group, a C₃-C₂₀ cycloalkyl group, and a C₆-C₂₀ aryl group, each unsubstituted or substituted with deuterium, a halogen atom, a cyano group, a hydroxyl group, an amino group, a carboxylate group, a thiol group, a carbonyl moiety, an ester moiety, a sulfonate moiety, a carbonate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

11. The polymer of claim 1, wherein p11 is 1.

12. The polymer of claim 1, wherein p21 is 0 or 1.

13. The polymer of claim 1, wherein
the first repeating unit is represented by Formula 1-1 below, and
the second repeating unit is represented by one of Formulae 2-1 and 2-2 below: 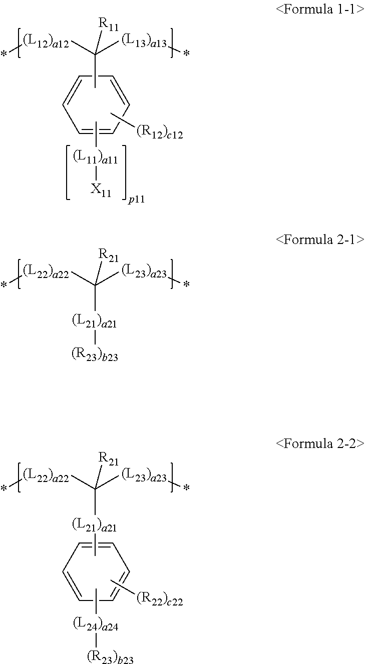
wherein in Formulae 1-1, 2-1, and 2-2,
L₁₁ to L₁₃, a11 to a13, X₁₁, R₁₁, R₁₂, and p11 are as defined in Formula 1,
c12 is an integer from 1 to 4,
L₂₁ to L₂₄, a21 to a24, R₂₁ to R₂₃, and b23 are as defined in Formula 2,
c22 is an integer from 1 to 4, and
* is a binding site with an adjacent atom.

14. The polymer of claim 1, wherein
the first repeating unit is selected from compounds of Group I below, and
the second repeating unit is selected from compounds of Group II below:

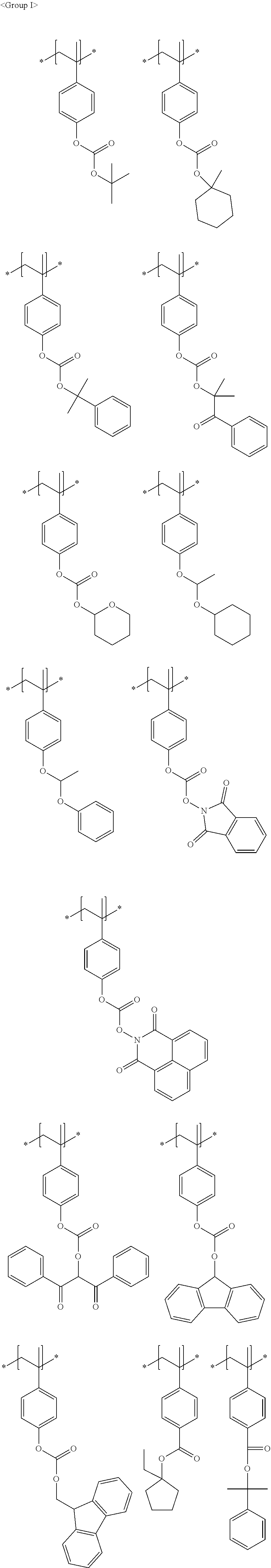

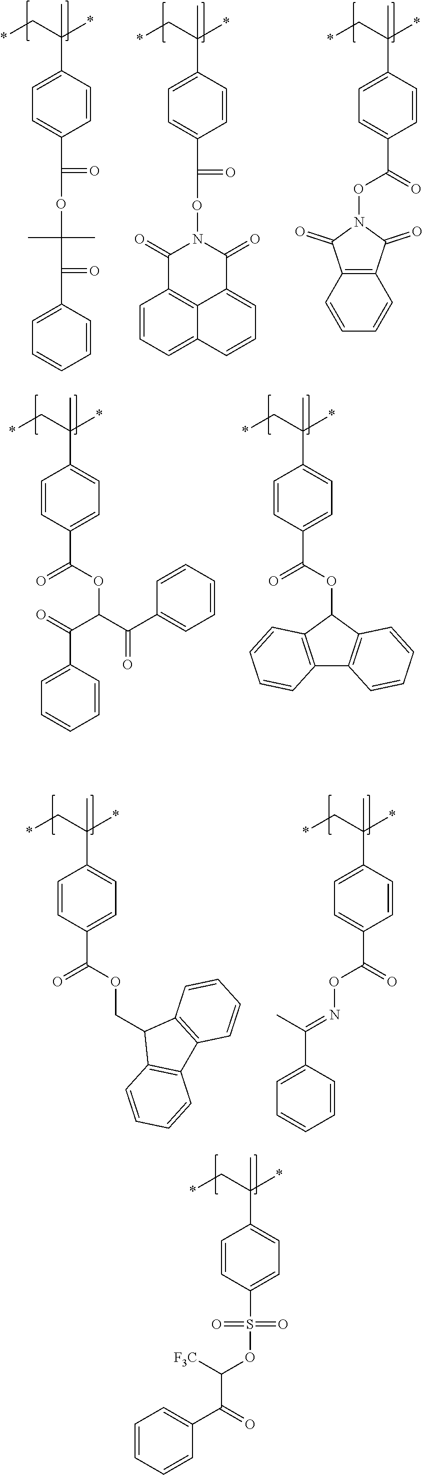

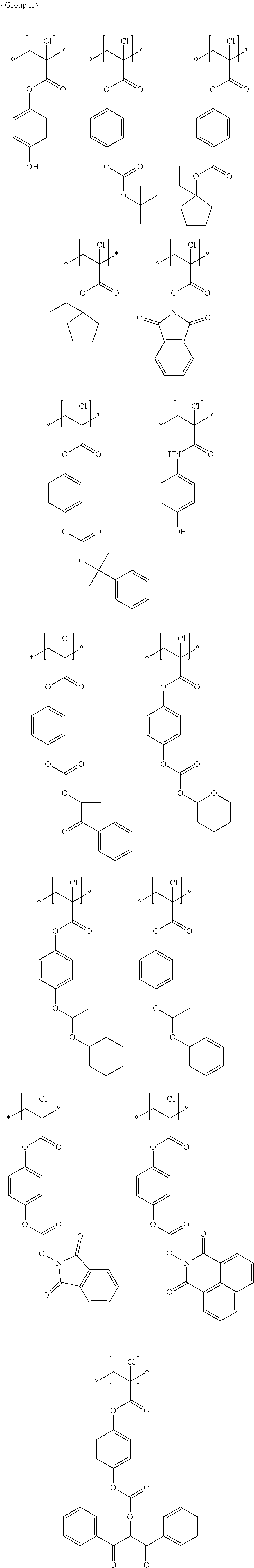

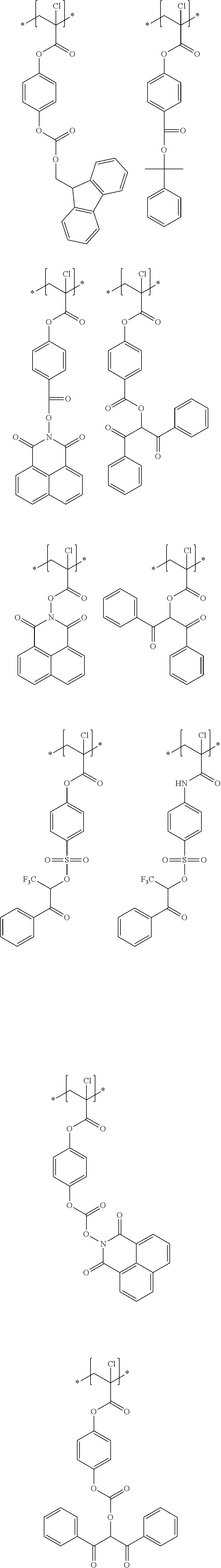

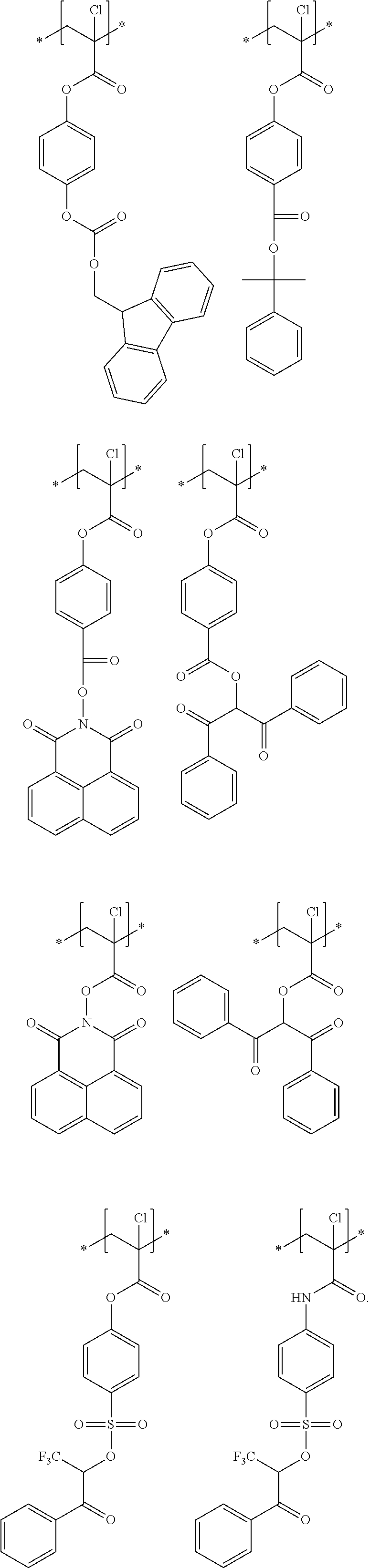

15. The polymer of claim 1, further comprising:
a third repeating unit represented by Formula 3 below: 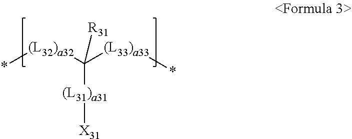
wherein in Formula 3,
L₃₁ to L₃₃ are each independently: a single bond; O; S; C(═O); C(═O)O; OC(═O); C(═O)NH; NHC(═O); S(═O)₂O; OS(═O)₂; or a linear, branched, or cyclic C₁-C₃₀ divalent hydrocarbon group optionally including a heteroatom,
a31 to a33 are each independently an integer from 1 to 4,
R₃₁ is: hydrogen; deuterium; a halogen atom; a cyano group; a hydroxyl group; an amino group; a carboxylate group; a thiol group; a carbonyl moiety; an ester moiety; a sulfonate moiety; a carbonate moiety; a lactone moiety; a sultone moiety; a carboxylic anhydride moiety; or a linear, branched, or cyclic C₁-C₃₀ monovalent hydrocarbon group optionally including a heteroatom,
X₃₁ is a photo-degradable group or a non-acid labile group, and
* is a binding site with an adjacent atom.

16. A resist composition comprising:
the polymer of claim 1; and
an organic solvent.

17. The resist composition of claim 16, further comprising:
an acid generator.

18. A method of forming a pattern, the method comprising:
forming a resist film by applying the resist composition of claim 16 on a substrate;
exposing a portion of the resist film to high-energy rays to provide an exposed resist film; and
developing the exposed resist film using a developer.

19. The method of claim 18, wherein the exposing the at least a portion of the resist film is performed by applying at least one of ultraviolet rays, deep ultraviolet (DUV) rays, extreme ultraviolet (EUV) rays, X-rays, γ-rays, electron beams (EBs), and α-rays.

20. The method of claim 18, wherein
the exposed resist film comprises an exposed region and a unexposed region, and
the exposed region is removed in the developing the exposed resist film by using the developer.
